(19) United States
(12) Patent Application Publication
(10) Pub. No.: US 2023/0184041 A1
(43) Pub. Date: Jun. 15, 2023

(54) WEAR CLASSIFICATION WITH MACHINE LEARNING FOR WELL TOOLS

(71) Applicant: Taurex Drill Bits, LLC, Norman, OK (US)

(72) Inventors: Dustin LYLES, Norman, OK (US); Warren DYER, Norman, OK (US); Tyler ABLA, Norman, OK (US)

(73) Assignee: Taurex Drill Bits, LLC, Norman, OK (US)

(21) Appl. No.: 18/169,582

(22) Filed: Feb. 15, 2023

Related U.S. Application Data
(63) Continuation-in-part of application No. 17/698,123, filed on Mar. 18, 2022.
Application No. 17/698,123 is a continuation of application No. 17/320,423, filed on May 14, 2021, now Pat. No. 11,301,989.
(60) Provisional application No. 63/024,754, filed on May 14, 2020.

(51) Int. Cl. E21B 10/42; G06T 7/00; E21B 12/02; G06T 7/30; G06T 11/00; G06T 7/11; G06F 30/28; G06F 30/10; G06F 18/24; G06F 18/214; G06V 20/64

(52) U.S. Cl. CPC E21B 10/42; G06T 7/001; E21B 12/02; G06T 7/30; G06T 11/00; G06T 7/11; G06F 30/28; G06F 30/10; G06F 18/24; G06F 18/214; G06V 20/647; G06T 2207/20081; E21B 2200/20; G06T 2207/30164; G06T 2207/20021

(57) ABSTRACT

Methods and systems for well tool wear classification system are provided. A wear classifier tool is configured to classify wear of a scanned well tool using a machine learning engine. Computer-readable memory stores a training dataset and a trained ML model. The training data set includes scanned image data and associated labels representative of classification types of failure. The trained ML model has a neural network. The wear classifier tool can output data identifying a failure mode of the scanned well tool based on classification of input by the machine learning engine. A database is configured to stored historical data on scanner type, patterns of scanner cutting elements, sensor type, and age and usage conditions. A scanning system includes a camera and a three-dimensional (3D) scanner configured to scan a drill bit.

### CROSS-REFERENCE TO RELATED APPLICATIONS

The present application is a continuation-in-part of U.S. patent application Ser. No. 17/698,123, filed on Mar. 18, 2022, which is a continuation of U.S. Pat. No. 11,301,989, filed on May 14, 2021, which is a non-provisional application claiming priority to U.S. Provisional Patent Application Ser. No. 63/024,754, filed May 14, 2020 (each of which is incorporated in its entirety herein by reference).

### BACKGROUND

In the oil and gas industry, several types of well tools are used downhole to perform various wellbore operations. Drill bits, for example, are commonly run downhole two or three (or more) times to drill a wellbore or extend its length. When a drill bit is new, its performance and drilling capability are fairly predictable and generally follow manufacturer specifications. In later stages, however, and due to uncertain operating and formation conditions, the drill bit will gradually wear and degrade into what is commonly referred to as a “dull” bit. Dull bits can slow the rate of wellbore penetration, thus requiring the drilling operator to apply more weight on bit, which, in turn, accelerates drill bit wear. Dull bits also often experience unbalanced side forces, which lead to whirl, vibration, and instability during operation. Consequently, when a drill bit becomes dull, it is commonly removed from operation and either scrapped or refurbished for subsequent use.

Determining whether a bit is scrapped or refurbished is typically based upon internal guidelines established by individual bit companies and experienced personnel within those companies. In addition to making determinations on repairability of dull bits, it is critical to document wear sustained on dull drill bits. The International Association of Drill Contractors (IADC) bit dull grading system was developed to provide a standardized protocol for evaluating drill bits to classify drill bit wear/damage and reason pulled. In the IADC dull grading process, a skilled evaluator visually inspects the dull bit and manually quantifies the observed wear using a standardized eight-field code with associated descriptors. The dull grading process, however, is a time-consuming process that is highly subjective, rarely repeatable, and often inaccurate.

Thus, what is needed is an improved method of determining and quantifying drill bit wear, which can lead to improved bit material selection, design optimization, and performance.

### BRIEF DESCRIPTION OF THE DRAWINGS

The following figures are included to illustrate certain aspects of the present disclosure, and should not be viewed as exclusive embodiments. The subject matter disclosed is capable of considerable modifications, alterations, combinations, and equivalents in form and function, without departing from the scope of this disclosure.

FIG. 1 is an isometric view of an example well tool that may incorporate the principles of the present disclosure.

FIG. 2 is a schematic diagram of an example scanning system that may incorporate the principles of the present disclosure.

FIG. 3 is a process flow diagram of an example method of determining and quantifying wear data on a well tool, according to one or more embodiments.

FIG. 4 depicts example solid model and scanned file outputs to which manual point pair alignment has been undertaken, according to one or more embodiments.

FIGS. 5A and 5B depict example digital features applied to specific wear parts of the drill bit of FIG. 1, according to one or more embodiments.

FIGS. 6A and 6B depict enlarged images of an example cutting element demonstrating area point cloud measurements, according to one or more embodiments.

FIGS. 7A-7D are example wear data reports that may be generated using an auto-generate report programming instruction, according to one or more embodiments.

FIG. 8 is an enlarged scanned view of a worn cutter seated within a corresponding cutter pocket, according to one or more embodiments.

FIG. 9A is an isometric view of an example cutting element after having sustained failure damage and depicting an extracted surface feature created based on the surface of the failure plane.

FIG. 9B is a graphical representation of missing portions of the cutting element

FIG. 10 depicts an example of computational fluid dynamics flow lines across a drill bit being correlated to cutting element wear, according to one or more embodiments.

FIG. 11 is a schematic diagram of the computer system of FIG. 2.

FIG. 12 is a diagram of a well tool wear classification system with machine learning, according to one or more embodiments.

FIG. 13 is a process flow diagram of a method for classifying well tools, according to one or more embodiments.

FIG. 14 is a diagram of a machine learning engine, according to one or more embodiments.

FIG. 15 shows images of different types of cutting element failures.

FIG. 16A, 16B and 16C show examples of automated radial position reporting for different cutting elements.

FIG. 17 is a schematic diagram of another example scanning system that may incorporate the principles of the present disclosure.

FIG. 18 shows two example images output by a wear classifier tool that show locations of cutting elements according to an embodiment.

FIG. 19 shows four example images of cutting elements for use in a training set.

FIG. 20 is a graph illustrating results of an example case study for a new cutter drill bit and incumbent cutter drill bit analyzed by a wear classifier tool according to an embodiment.

FIG. 21 shows images of different types of substrate damage that are classified and determined by a wear classification tool in a further embodiment.

### DETAILED DESCRIPTION

The present disclosure is related to analyzing well tools and, more particularly, to scanning used well tools with three-dimensional or two-dimensional imaging systems and subsequently quantifying wear data.

Embodiments of the present disclosure describe methods of analyzing well tools to determine and quantify wear data. According to methods disclosed herein, a used well tool is scanned and the resulting scanned file is aligned with and compared with a solid model (e.g., CAD model) of the well tool in its as-designed state. Material loss can then be measured directly for analysis by subtracting the scanned parts from the corresponding solid model parts. One issue with conventional scanning of well tools is that the scan data is commonly represented as a single surface geometry that lacks any distinction between individual, discrete components of the well tool. Because the individual components are not discrete 3D solids in conventional scanning techniques, they cannot be easily measured.

Assemblies made up of various parts subject to wear are of interest in defining the amount of wear experienced during operation of the assembly. The presently described methods facilitate measurement of discrete volumetric and/or area wear of components and parts of well tools. The methods disclosed herein provide improved consistency, granularity (i.e., characterization), and accuracy of wear data as feedback for application specific well tool selection, design optimization, and material selection. In some cases, formation characteristics can be correlated to wear identified on well tool cutting elements, thus enabling indexing of formation abrasion, thermal and/or impact severity and probability.

Moreover, the wear or wear rate of specific materials in the well tools can be tracked over time to ensure there is no drifting of performance due to changes in materials and/or manufacturing. Wear and wear rate can also be tracked to better understand variations in lithology and/or drilling parameters of subterranean formations. Furthermore, the methods described herein may help enhance a manufacturer's ability to perform economic analysis and make material selections for well tools based on a rate of return from a performance perspective. Thus, the methods discussed herein provide quick and reliable feedback to manufacturers, operators, and tool companies to aid in optimization of drilling efficiency and economics.

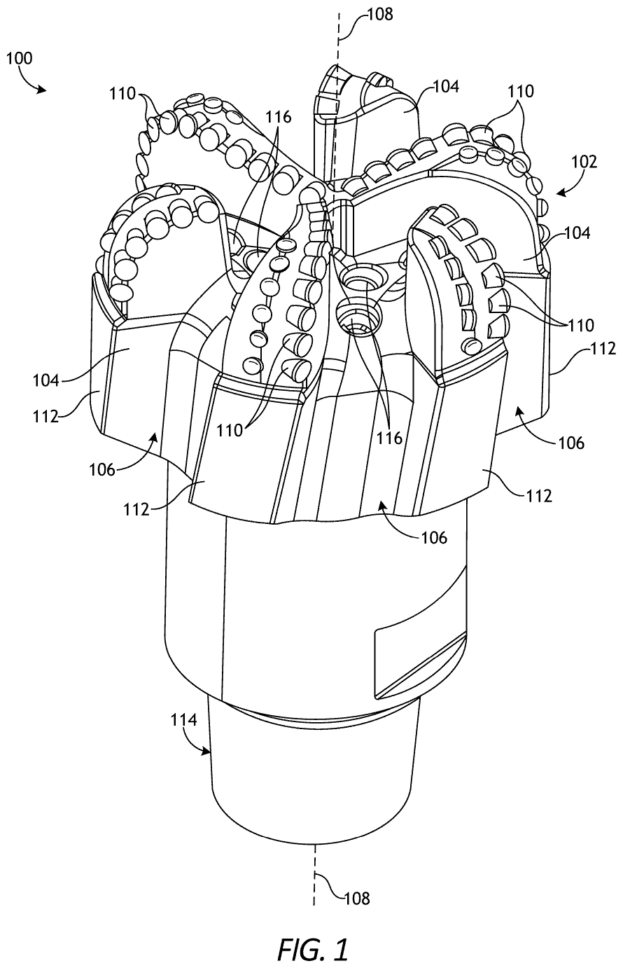

FIG. 1 is an isometric view of an example well tool 100 that may incorporate the principles of the present disclosure. In the illustrated embodiment, the well tool 100 comprises a rotary drill bit, but the principles of the present disclosure are equally applicable to other well tools commonly used in the oil and gas industry and corresponding to a wide variety of oilfield equipment (both surface and subsurface), well drilling equipment, well drilling tools, well completion equipment, well completion tools, well service tools, well service equipment, and/or associated components. Other examples of the well tool 100 include, but are not limited to, bit bodies associated with rotary drill bits, fixed cutter drill bits (e.g., PDC bits), drill string stabilizers, roller cone drill bits, cones for roller cone drill bits, rotary steering tools (e.g., directional tools), logging while drilling tools, measurement while drilling tools, side wall coring tools, underreamers, fishing spears, washover tools, whipstocks, production packer components, float equipment, casing shoes (e.g., a casing shoe with cutting structures), well screens, gas lift mandrels, downhole tractors, tool joints, rotors, stator and/or housings for downhole motors, blades and/or housings for downhole turbines, latches for downhole tools, and other downhole tools associated with drilling and completing a wellbore.

In the present discussion, the well tool 100 will be described with reference to the rotary drill bit depicted in FIG. 1. Consequently, the well tool 100 will alternatively be referred to herein as the “drill bit 100” or the “rotary drill bit 100”. The term “rotary drill bit” refers to various types of fixed cutter drill bits, drag bits, matrix drill bits, steel body drill bits, roller cone drill bits, rotary cone drill bits, and rock bits operable to form a wellbore. As will be appreciated, rotary drill bits and associated components incorporating the teachings of the present disclosure may have many different designs, configurations, and/or dimensions.

As illustrated, the drill bit 100 includes a generally cylindrical bit body 102 that provides or otherwise defines one or more drill bit blades 104 separated by junk slots 106. The blades 104 may be provided in a wide variety of configurations including, but not limited to, substantially arched, helical, spiraling, tapered, converging, diverging, symmetrical, asymmetrical, or any combination thereof. In the illustrated embodiment, some of the blades 104 extend to a centerline 108 of the bit body 102 and may be referred to as “primary” blades, while other blades 104, referred to as “secondary” blades, do not extend to the centerline 108 and operate to “follow” the primary blades 104 during operation.

The bit body 102 can be formed integrally with the blades 104, such as being milled out of a steel blank. Alternatively, the blades 104 can be welded to the bit body 102. In other embodiments, the bit body 102 and the blades 104 may be formed of a matrix material (e.g., tungsten carbide matrix with an alloy binder) sintered and/or cast in a mold of a desired shape, with the blades 104 also being integrally formed of the matrix with the bit body 102.

The drill bit 100 further includes a plurality of cutting elements 110 (alternately referred to as “cutters”) fixed to the blades 104. In some cases, some of the cutting elements 110 may be mounted at the leading face of some or all of the blades 104. Each cutting element 110 may be received within and bonded to a dedicated cutter pocket machined or cast into the bit body 102 at the corresponding blade 104. One or more of the cutting elements 110 may include a cutting table or face bonded to a substrate secured within a corresponding cutter pocket. The cutting table may be made of a variety of hard or ultra-hard materials such as, but not limited to, polycrystalline diamond (PCD), sintered tungsten carbide, thermally stable polycrystalline (TSP), polycrystalline boron nitride, cubic boron nitride, natural or synthetic diamond, hardened steel, or any combination thereof. The substrate may also be made of a hard material, such as tungsten carbide or a ceramic.

In other embodiments, however, one or more of the cutting elements 110 may not include a cutting table. In such embodiments, the cutting elements 110 may comprise sintered tungsten carbide inserts without a cutting table and bonded to corresponding cutter pockets. The cutting elements 110 may be bonded to the corresponding blade 104 such that they are fixed or alternately allowed to rotate.

The cutting elements 110 may comprise any suitable cutter designed to cut, gouge, and/or scrape into underlying rock formations as the bit body 102 rotates during downhole operation. The cutting elements 110 can include primary cutting elements, back-up cutting elements, secondary cutting elements, or any combination thereof. In some applications, other types of cutting elements may be fixed to various portions of the primary or secondary blades 104.

Such cutting elements can include, but are not limited to, cutters, compacts (e.g., polycrystalline diamond compacts or “PDC”s), buttons, inserts, and gage cutters suitable for use with a wide variety of drill bits. In some cases, the blades 104 may also include one or more depth of cut controllers (DOCCs) configured to control the depth of cut of the cutting elements 110. Various features may also be affixed to the blades 104 to mitigate vibration.

Moreover, the drill bit 100 may further include one or more gauge pads 112 provided on outer radial portions of the blades 104 to contact radially adjacent portions of the drilled wellbore. The gauge pads 112 operate to provide added stability and protection to gauge cutting elements (if any) while maintaining a predetermined diameter of the drilled wellbore. The gauge pads 112 may also contain one or more cutting elements in order to enhance the ability of the well tool to maintain a properly gauged well bore.

The drill bit 100 further includes a pin 114 that defines American Petroleum Institute (API) drill pipe threads used to releasably engage the drill bit 100 with drill pipe or a bottom-hole assembly (BHA) whereby the drill bit 100 may be rotated relative to the centerline 108. In example operation, as the drill bit 100 advances into the earth, a drilling fluid (e.g., water, drilling mud, etc.) is communicated to one or more nozzles 116 provided in the bit body 102 to cool and lubricate the drill bit 100. The drilling fluid is discharged from the nozzles 116 and into the junk slots 106, and a mixture of drilling fluid, formation cuttings, and other downhole debris flow through the junk slots 106 to be returned to the well surface via the annulus of the drilled wellbore.

Operation of the drill bit 100 in downhole environments inevitably causes wear and tear on the drill bit 100, which gradually decreases its efficiency and effectiveness. Eventually the decreased drilling efficiency of the drill bit 100 outweighs the drilling interests and the drill bit 100 must be returned to the surface and replaced or refurbished.

As indicated above, dull bits are either scrapped or refurbished for subsequent use and, in some cases, this determination is reached by a skilled evaluator. Because the dull grading process is time-consuming, highly subjective, and often inaccurate, other wear analysis techniques have been developed to provide more efficient means of wear data quantification. For example, worn well tools, such as drill bits, can be digitally scanned to obtain and process three-dimensional (3D) images of the worn well tools that help manufacturers determine whether a worn well tool should be scrapped or refurbished. Moreover, metrology software has been developed to calculate wear by comparing separate models, but conventional scanning techniques quantify wear (i.e., deviation) for a body as a whole, and are not designed to distinguish wear/deviation for separate, distinct parts or components within one scanned image. More specifically, conventional methods of scanning well tools to determine material loss (volumetric and/or area) typically generate scan data represented as a single, monolithic surface geometry that lacks any distinction between the individual, discrete components (parts) of the well tool. Because the individual components are not discrete 3D solids, they cannot be measured independently but only as part of the whole. It is believed that no solution has previously been disclosed that automates material loss/wear calculations for individual, discrete wear parts or components of a well tool.

According to the present disclosure, when evaluating the wear state and characteristics of a well tool, such as the drill bit 100, wear is linked and/or correlated to specific regions or “wear parts” of the well tool. As used herein, the term “wear parts” refers to parts, components, or regions of a well tool that have a higher susceptibility to wear and tear during operation as compared to other parts, components, or regions of the well tool. Wear parts on the drill bit 100, for example, include at least the blades 104, the cutting elements 110, and the gauge pads 112 due to the significant variation of forces applied to these individual regions across the bit profile. In some embodiments, wear parts can also include depth of cut controllers (DOCCs), if present. Additionally, these separate regions of the bit profile experience various forms and severity of impact loading/instability, perform varying degrees of work, travel at varying speeds, and travel highly variable distances.

The methods described herein automate the process of scanning a worn well tool, selecting wear parts of interest on a three dimensional solid model of the well tool generated by means of computer-aided design (CAD) software, aligning the solid and scanned models of the well tool, and calculating the deviation (wear) between the scanned part and the solid model part, thus providing a user (e.g., an operator, a tool company, etc.) with the material loss (volumetric and/or area) at the wear parts of interest. As will be appreciated, the methods described herein may be advantageous over the time-consuming and subjective manual process of analyzing dull drill bits. Whereas manually analyzing a dull drill bit can require several hours of manual labor, the methods disclosed herein can be accomplished in just minutes.

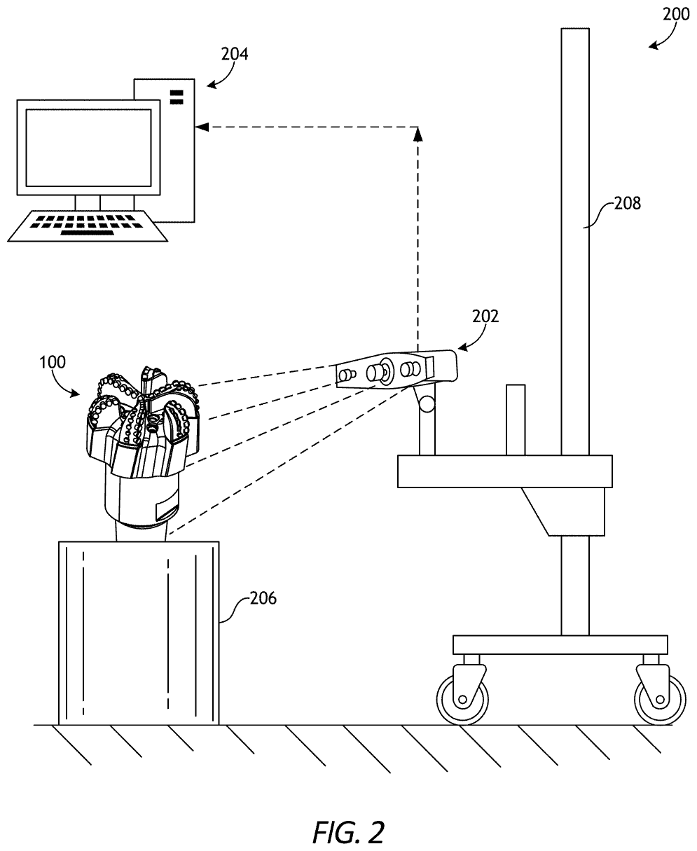

FIG. 2 is a schematic diagram of an example scanning system 200 that may incorporate the principles of the present disclosure. The scanning system 200 (hereafter “the system 200”) may be configured to scan a well tool, such as the drill bit 100. As illustrated, the scanning system 200 includes a scanner 202 and a computer system 204 in communication with the scanner 202. In some embodiments, the computer system 204 may include two or more computers (e.g., multi-pc workflow) networked together or otherwise capable of communicating one with the other. Having more than one computer may be advantageous in increasing capacity (e.g., maximizing number of well tools scanned without delay due to inspection) while creating real-time/simultaneous inspections upon completion of a scan. In such embodiments, for example, the computer system 204 may include a scanning computer separate from an inspection computer, among other computer devices.

The scanner 202 may be positioned to obtain scanned images of the drill bit 100, which may be positioned on a stand 206. In some embodiments, the scanner 202 may be designed to obtain three-dimensional (3D) images of the drill bit 100 and may thus comprise a type of 3D scanner or 3D scanning system. For purposes of this disclosure, the term “3D scanner” or “3D scanning system” refers to any assembly by which distance data may be collected or calculated and reconstructed to extrapolate the shape of an object (e.g., a well tool). Such assemblies may refer to any kind of 3D scanning system, including contact or non-contact 3D scanners, such as a time-of-flight 3D laser scanner, a triangulation 3D scanner, a structured light 3D scanner, an optical 3D scanner, stereoscopic scanners, general photography devices, or any combination thereof. Further, in one or more embodiments, the 3D scanning system may be an internal component of an electronic device or a separate external component connected to an electronic device operable at will by a user.

In other embodiments, however, the scanner 202 may be designed to obtain high-resolution two-dimensional (2D) images of the drill bit 100, without departing from the scope of the disclosure. In such embodiments, the scanner 202 may comprise a high-resolution camera or the like capable of obtaining high-resolution 2D photographic (still) images and/or video. Moreover, in such embodiments, the computer system 204 may be programmed or otherwise configured to implement photogrammetry techniques to gather measurements and data about the well tool by analyzing the change in position from two or more different images. Accordingly, the principles of the present disclosure are equally applicable to 2D scanning operations. In some embodiments, the scanner 202 may be mounted to a support assembly 208 capable of moving the scanner 202 about the drill bit 100 to capture scanned images (3D or 2D) of all exterior portions of the drill bit 100. The support assembly 208 may include, for example, one or more robotic arms and/or lifts that may help maneuver and position the scanner 202 at all required angles and locations relative to the drill bit 100. In some embodiments, the support assembly 208 may be automated, but may alternatively be manually operated. In some embodiments, the scanner 202 may remain stationary and the stand 206 may alternatively be rotatable and/or movable up and down to help enable adequate scanning of the drill bit 100. In yet other embodiments, the scanner 202 may comprise a hand-held scanning system and a user or operator may hold the scanner 202 and walk around the periphery of the drill bit 100 while digitally “painting” the drill bit 100 with the scanner 202 to obtain the necessary scanned images (3D or 2D).

In some embodiments, the drill bit 100 may be prepared for scanning, such as by applying reflective markers to assist in stitching the 3D scan together, applying matting spray to remove reflective glare, and the like. The scanner 202 may be designed to operate with an accuracy of approximately 0.0005-0.003 inches or better.

The scanner 202 may communicate with the computer system 204 via any known wired or wireless means. In at least one embodiment, the computer system 204 may comprise one component of a larger computer network. The computer system 204 may include a processor and a non-transitory, computer readable medium (i.e., a memory) programmed with computer-executable instructions that, when executed by the processor, perform the methods described herein. More particularly, the computer system 204 may have 3D modeling and metrology software stored thereon, which may include instructions to receive and process images captured by the scanner 202 and generate a 3D image of the drill bit 100 based on the captured images. For example, computer system 204 may be programmed or otherwise configured to implement photogrammetry techniques to build a textured or colored 3D model of a well tool drill bit 100.

The 3D image of the drill bit 100 may comprise a scanned “mesh” file (e.g., .stl, point cloud, IGES, STEP, etc.) comprising a complex polygon mesh structure corresponding to the scanned dimensions and configurations of the drill bit 100 as obtained by the scanner 202. As described in more detail below, the scanned file of the drill bit 100 may be compared against a solid model (e.g., a computer-aided design or CAD solid model) file of the drill bit 100 corresponding to the original manufacturer specifications for the drill bit 100. The scanned file may be spatially aligned with the corresponding solid model file and any deviation between individual scanned parts (regions) and the corresponding solid model parts may be indicative of how much wear the drill bit 100 experienced during operation. Such comparisons may be used to quantify, often in a digital format, specific amounts of abrasion, erosion, and/or wear of associated blades 104 (FIG. 1), cutting elements 110 (FIG. 1), and/or gauge pads 112 (FIG. 1), for example.

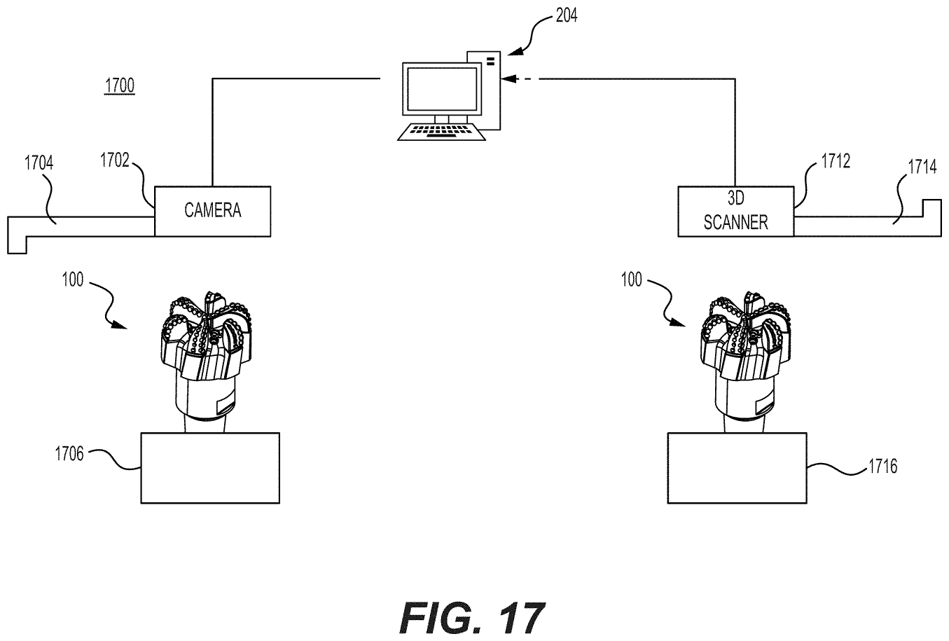

FIG. 17 is a schematic diagram of another example scanning system 1700 that may incorporate the principles of the present disclosure. Scanning system 1700 includes a 2D scanner (such as camera 1702) and a 3D scanner 1712. Camera 1702 can be positioned relative to a drill bit 100 to capture images (e.g., 2D images) of drill bit wear during a scanning operation as described above with respect to FIG. 2. Drill bit 100 may be positioned on a stand 1706. A robotic arm 1704 may be used to move camera 1702 relative to the drill bit 100 and stand 1706. Computer system 204 may be coupled to camera 1702 and robotic arm 1704 to control scanning of drill bit 100 and capture of images by camera 1702. Camera 1702 is illustrative and can be a digital camera, such as, an area image sensor, a line image sensor moved over an area, or other type of 2D scanner.

3D scanner 1712 can be positioned relative to a drill bit 100 to capture images of drill bit wear and distance data (3D images) during a scanning operation as described above with respect to FIG. 2. Drill bit 100 may be positioned on a stand 1716. A robotic arm 1714 may be used to move 3D scanner 1712 relative to the drill bit 100 and stand 1716. Computer system 204 may be coupled to 3D scanner 1712 and robotic arm 1714 to control scanning of drill bit 100 and capture of images and distance data by 3D scanner 1712.

In one embodiment, system 1700 performs 2D scanning and 3D scanning in series on multiple drill bits 100. A first drill bit 100 is scanned by camera 1702 to capture 2D images. Afterwards, drill bit 100 is scanned by 3D scanner 1712 to capture 3D images, while a second drill bit is scanned by camera 1702. This process can be repeated to scan multiple drill bits for wear. Captured 2D images and 3D images are stored in a database or other memory coupled to computer system 204. Computer system 204 can then process the captured 2D images and 3D images and distance data to determine and classify wear, and/or to predict repair or replace with machine learning as described further below.

In one embodiment, captured 2D images represent images of a drill bit 100 taken from different camera positions in a scan. This can include images of blades, cutting elements, bit body, shank, or pin taken from different camera positions and can be tied to a work order and used to store generate reports or other wear analysis. Captured 3D images can be used as input data for a machine learning engine to determine and classify wear, and/or to predict repair or replace with machine learning, such as, deep learning using one or more neural networks. .

In one embodiment the 2D scanning by a camera and subsequent failure mode classification by a trained ML model operates independently of the 3D scanning, whereby the trained ML model only classifies failure modes while the 3D model and automated metrology inspection process quantifies the material loss (wear).

In another embodiment the output data from the 2D and 3D processes are compared to one another to improve the accuracy of the ML model and wear quantification and/or failure mode and produce a secondary/resulting, optimized output data. This comparison can improve accuracy. In some cases, there can be inherent inaccuracies in both 2D and 3D scanning processes so comparing the two results can improve accuracy of each. For example, a resolution of a 3D mesh model may have some distortion on the edge of cutting elements that result in biasing of the diamond area removed calculation, and thereby calculating missing diamond when in fact the cutter is fully intact. The high resolution 2D image processed through the ML model would determine there is no wear on the cutter and thus the wear calculation from the 3D model in the metrology inspection could be corrected, producing more accurate measurement.

Furthermore, a trained ML model may be used in the well classifier tool to make a determination on whether a cutting element should be replaced or if it can be rotated in the pocket to expose a new, unworn portion of the cutting element. For example, one or more cutting elements may be determined by the well classifier tool to be in need of rotation in which case the well tool is rotated to expose unused portions of the cutting elements such as those at the circumference of the well tool. The well classifier tool may evaluate wear or damage based on whether a threshold or other metric is exceeded which requires rotation, or if rotation is unacceptable to correct the classified wear then replacement.

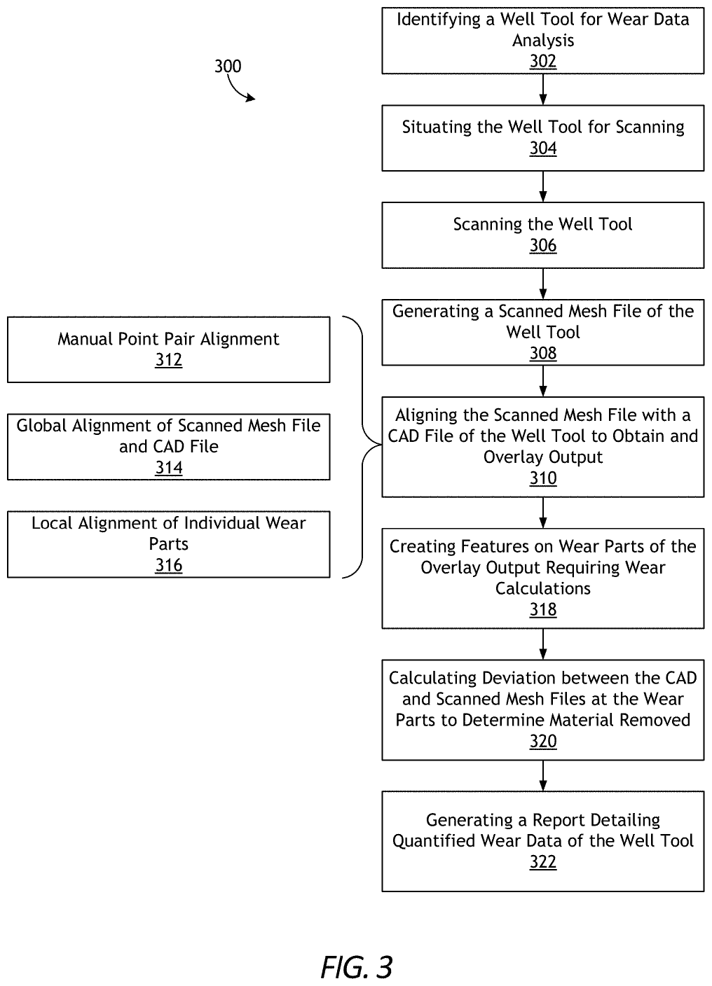

FIG. 3 is a process flow diagram of an example method 300 of determining and quantifying wear data on a well tool, according to one or more embodiments. The method 300 will be discussed with respect to determining and quantifying wear data of the drill bit 100 of FIGS. 1-2, but it will be appreciated that the method 300 may alternatively be used to determine and quantify wear data of any of the well tools or associated components mentioned herein.

Moreover, the method 300 may also incorporate and use the scanner 202 (FIG. 2) and the computer system 204 (FIG. 2) described herein to help determine and quantify the wear data.

As illustrated, the method 300 may first include identifying a well tool for wear data analysis, as at step 302. The well tool must be properly identified in order to be able to run the software programming instructions that facilitate automated wear data quantification. In this step, the dull drill bit 100 (or any other well tool mentioned herein) may be identified by the computer system 204 (FIG. 2) based on original design and preparation files used to manufacture the drill bit 100. The design and preparation files can include, but are not limited to, solid models (e.g., CAD files) and data files (e.g., comma separated variable or “CSV” files) corresponding to the drill bit 100, and may be prepared based on tool features such as part number, outer diameter, cutter size, blade count, etc. In at least one embodiment, the data file could be programmatically generated based on the embedded parts and details provide in the solid model file. More specifically, an operator may be able to merely input a part number or the like and the computer system 204 may be configured to pull the necessary data file information from the solid model file. In such embodiments, the information for the data file may be embedded within the solid model file or otherwise within the bit manufacturer's bit design database.

Both the solid model and data files will be separable into common wear parts of the drill bit 100, such as the blades 104 (FIG. 1), the cutting elements 110 (FIG. 1), and the gauge pads 112 (FIG. 1). Furthermore, individual cutting elements such as PDC cutters could be separated into the two main components, PDC diamond table and tungsten carbide substrate. This separable data will be required to enable the computer system 204 to run the wear data quantification programming instructions (e.g., macros) described herein and obtain wear data quantification for individual (discrete) wear parts, as opposed to a volumetric material loss for the drill bit as a whole, or performing manual procedures to quantify wear.

The solid model file may be saved in the computer system 204 (FIG. 2) such that the common wear parts of the drill bit 100 are separately identified but embedded in a main assembly file. Accordingly, the main assembly file is comprised of the bit body 102 (FIG. 1) along with the wear parts and any other discrete parts or components that are cast, welded, or otherwise attached to the bit body 102.

Similarly, the data file may be saved in the computer system 204 (FIG. 2) with separate wear parts of the drill bit 100 being separately identifiable, as is common to data files. More specifically, the data file may include various part parameters related to the drill bit 100, such as bit size, bit description, scale CAD factor, the CAD part name for each cutting element 110 (FIG. 1), a list of cutting element 110 numbers (as assigned in the main assembly CAD file), the CAD part name for each blade 104 (FIG. 1), the corresponding blade 104 number for each cutting element 110, the nominal area/volume value for each cutting element 110, wear tolerances (if applicable/desired), nominal gauge diameter for the bit body 102 (FIG. 1), DOCC elements, and features of any DOCC elements.

In the event some of the cutting elements 110 comprise shaped (non-cylindrical) cutters, which exhibit a different nominal value than traditional cylindrical cutters, the data file may include (indicate) the appropriate nominal value for each cutting element 110. In some embodiments, for example, shaped and cylindrical cutting elements 110 may be used in an alternating layout along the blades 104 (FIG. 1) based on the radial position of the cutters on the profile. In such embodiments, the appropriate nominal area value may be applied to the varying cutter geometries to ensure accurate area/volume wear measurements, which would otherwise be erroneous if only one nominal value were applied to all cutting elements 110.

The well tool may then be properly situated in preparation for scanning, as at 304. The drill bit 100, for example, may be positioned on the stand 206 (FIG. 2) adjacent the scanner 202 (FIG. 2). In some embodiments, properly situating the drill bit 100 on the stand 206 may entail aligning one of the blades 104 (FIG. 1) with a predetermined angular orientation or coordinate (e.g.,) 270°. Such alignment may prove advantageous in enabling operators (e.g., scanner operators) to automate subsequent scanning processes with drill bits having the same part number. In other embodiments, a fixturing apparatus could be used to facilitate consistent alignment of the well tool when situating the well tool on a stand for scanning. In this scenario, the fixturing would also be modelled with the well tool to aid in alignment. In yet other embodiments, a datum feature could be designed into the well tool to allow for a datum-based alignment process.

Various tool data corresponding to the drill bit 100 may then be uploaded to the computer system 204 (FIG. 2) by the user to enable the computer system 204 to subsequently relate a scanned file of the drill bit 100 with the design and preparation CAD and data files. Example tool data that may be uploaded include, for instance, the part number, the serial number, and operation information for the drill bit 100. The operation information refers to where the drill bit 100 was used (commissioned), and such information may be subsequently correlated to the wear data. In some embodiments, the tool data corresponding to the drill bit 100 may be manually uploaded to the computer system 204. In other embodiments, however, the tool data may be obtained and uploaded electronically, such as by scanning a barcode corresponding to the specific drill bit 100, which will automatically upload the corresponding tool data from a database or data file, or both.

The well tool may then be scanned, as at 306. As indicated above, the scanner 202 (FIG. 2) may be operated to obtain multiple scanned images (3D or 2D) of the drill bit 100 from all angles and covering all exterior surfaces of the drill bit 100. These images may be subsequently transmitted to the computer system 204 (FIG. 2) for processing and generation of a scanned file corresponding to the drill bit 100, as at 308.

Once the scan of the well tool is complete, the computer system 204 may be programmed to run a first or “data import and preparation” programming instruction. In some embodiments, the 3D modeling and metrology software stored on the computer system 204 is automatically opened upon scan completion, and the 3D modeling and metrology software may be programmed to run the data import and preparation programming instruction. The data import and preparation programming instruction instructs the computer system 204 to import the 3D images obtained by the scanner 202 (FIG. 2) and generates the scanned file from the 3D images.

As provided above, the scanned file consists of a 3D model comprising a complex polygon mesh structure corresponding to the scanned dimensions and configurations of the drill bit 100.

The data import and preparation programming instruction also instructs the computer system 204 to load the applicable design and preparation files corresponding to the drill bit 100. More specifically, the solid model files related to the drill bit 100 are loaded based on the tool data entered by the user prior to scanning the drill bit 100; e.g., the part number, the serial number, etc. of the drill bit 100. Moreover, the solid model files may be organized and renamed based on the dialogue tree of the data (e.g., CSV) files corresponding to the drill bit 100. This may be advantageous in organizing the cutting elements 110 (FIG. 1) by blade 104 (FIG. 1) and relative cutter position for subsequent feature generation, wear calculations, and reporting. In some applications, the dialogue tree includes the main assembly CAD model expanded with a view of the embedded parts of the well tool. The dialogue tree can include native naming and organization of other embedded parts that make up the main assembly. For example, the cutting elements 110 (FIG. 1) can be designated in the dialogue tree for wear calculations in an updated organization and naming sequence to facilitate preferred reporting. In at least one embodiment, the dialogue tree includes branch names, object names (including measurements, color maps, etc.), index numbers, and icons.

The method 300 may further include aligning the scanned file of the well tool with the solid model file corresponding to the well tool to obtain an overlay or “mated” output, as at 310. In some embodiments, properly aligning the scanned file with the solid model file may comprise three or more alignment steps or stages that may be performed to ensure proper alignment for the subsequent programming instructions that will be run to accurately record wear data. In the first alignment step, the data import and preparation programming instruction may prompt the user to undertake a manual point pair alignment between the scanned file and the corresponding solid model file, as at 312. Manual point pair alignment may be used to generally align the scanned file with the solid model file, and helps positively locate and identify wear parts of interest in the drill bit 100, such as each cutting element 110 (FIG. 1), each blade 104 (FIG. 1), and each gauge pad 112 (FIG. 1). This can be done by marking particular surfaces or parts on the solid model file with a unique identifier, and then making a corresponding mark on the same surfaces or parts of interest provided by the scanned file.

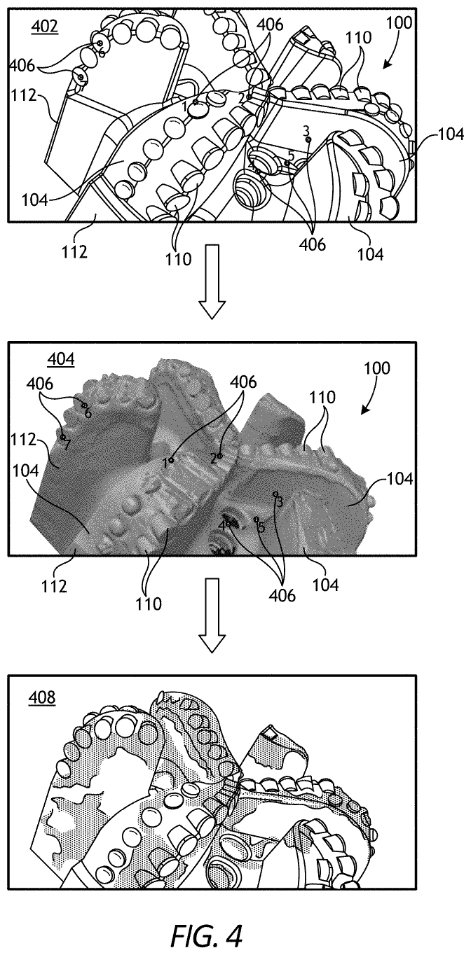

Referring briefly to FIG. 4, illustrated is an example solid model file output 402 and an example scanned file output 404 on which manual point pair alignment has been undertaken, according to one or more embodiments. As illustrated, several particular surfaces and parts of the drill bit 100 have been manually (e.g., electronically via a computer) marked by the user on the solid model file output 402 with unique identifiers 406. Corresponding marks in similar locations have also been manually placed on the scanned file output 404 with the same unique identifiers 406 to indicate the same surfaces and parts of interest, thus linking the solid model file to the scanned file. Consequently, the cutting elements 110 included in the solid model file will be aligned with the corresponding cutting elements 110 provided in the scanned file, the blades 104 included in the solid model file will be aligned with the corresponding blades 104 provided in the scanned file, and the gauge pads 112 included in the solid model file will be aligned with the corresponding gauge pads 112 provided in the scanned file.

The result of the manual point pair alignment is an overlay (mated) output 408 of the CAD and scanned files, which provides a rough alignment of the two file outputs 402, 404. In some embodiments, the manual point pair alignment may require 5 to 20 or more unique identifiers 406 to be placed on both the solid model file output 402 and the scanned file output 404 to achieve the rough alignment. In at least one embodiment, the manual point pair alignment step 312 may alternatively be automated by using datums and cutter position files.

Referring again to FIG. 3, in one or more embodiments, the manual point pair alignment of step 312 may be required only for new (unknown or not previously scanned) well tools with new (unknown) part numbers. For example, when a subsequent drill bit having the same part number as the drill bit 100 is scanned, the data import and preparation programming instruction may be configured to automate the point pair alignment for the subsequent drill bit since its features and design will be the same as the previously scanned and aligned drill bit 100. Automating the point pair alignment for additional well tools with same part numbers may be possible, however, only if the well tools are properly situated (oriented) and aligned for scanning, as discussed above in step 304.

Once the point pair alignment occurs, a second alignment step may ensue to globally align the scanned file with the solid model file, as at 314. More specifically, the data import and preparation programming instruction may then trigger a global alignment performed within the 3D modeling and metrology software that takes the rough point pair alignment and transforms it to a tighter alignment. In this process, a best-fit global alignment is created between all surfaces of the scanned mesh and solid model file outputs 402, 404 (FIG. 4), which provides a more accurate alignment between the scanned mesh and solid model files. In this process, all surfaces of the well tool may be utilized to achieve a best-fit alignment.

In some embodiments, a third alignment step may then be undertaken to perform a local alignment of individual wear parts of the well tool requiring wear calculations, as at 316. The third alignment step takes into consideration shrinkage in manufacturing processes of cast bits that may cause the scanned file to deviate from the solid model file based on manufacturing deviations or tolerances. More specifically, this step is designed to remove inconsistencies in positioning of the wear parts between the solid model and scanned files that result from shrinkage and/or deviations inherent in any manufacturing processes. This is accomplished by performing alignments on the individual wear components on an individual basis, thus eliminating the bit body and any positioning inconsistencies. Without this step, if a given wear part were out of position by even a small degree, the point clouds would not represent the wear part but rather the region surrounding the wear part.

In some embodiments, step 316 may alternatively be accomplished using a local best fit to critical feature alignment method. The local best fit to critical feature alignment may be undertaken to improve local cutter alignment if a substantial portion of the tungsten carbide substrate or cutting/diamond table are worn or missing. For instance, if the tungsten carbide substrate on the back portion of the cutter has suffered severe erosion, the alignment step could be skewed because so much of the feature is missing. An improved alignment could be performed by aligning only “critical features” of the cutter that did not sustain wear. In this example, this may entail using the cutting/diamond table only for alignment purposes. As will be appreciated, the inverse could be applied if the cutting/diamond tables are substantially worn or missing. The local best fit to critical feature alignment method may be done manually by an operator, or the process may be automated using the computer system 204.

In some embodiments, the data import and preparation programming instruction in the third alignment step 316 may be programmed to provide local alignment of each cutting element 110 (FIGS. 1 and 4) and cutter cylinder of the scanned file with the corresponding portions of the 3D file. This step reduces the alignment process to only cutter surfaces since without accurate local cutter-to-cutter alignment, the resulting wear data would be erroneous. As a result, each cutting element 110 is aligned on a one-by-one basis for optimal alignment, and regardless of deviations present between the scanned mesh and solid model files.

Once the alignment sequence(s) is/are complete, as at 310, the method 300 may then proceed to create features on wear parts of the scanned file requiring wear calculations, as at 318. More specifically, once alignment is complete and the overlay output 408 (FIG. 4) is generated, the computer system 204 may be programmed to run a second or “create dimensions” programming instruction, which may be programmed into the 3D modeling and metrology software. The create dimensions programming instruction may be configured to create and place digital features on specific wear parts of the overlay output 408 of the drill bit 100 that will undergo wear calculations.

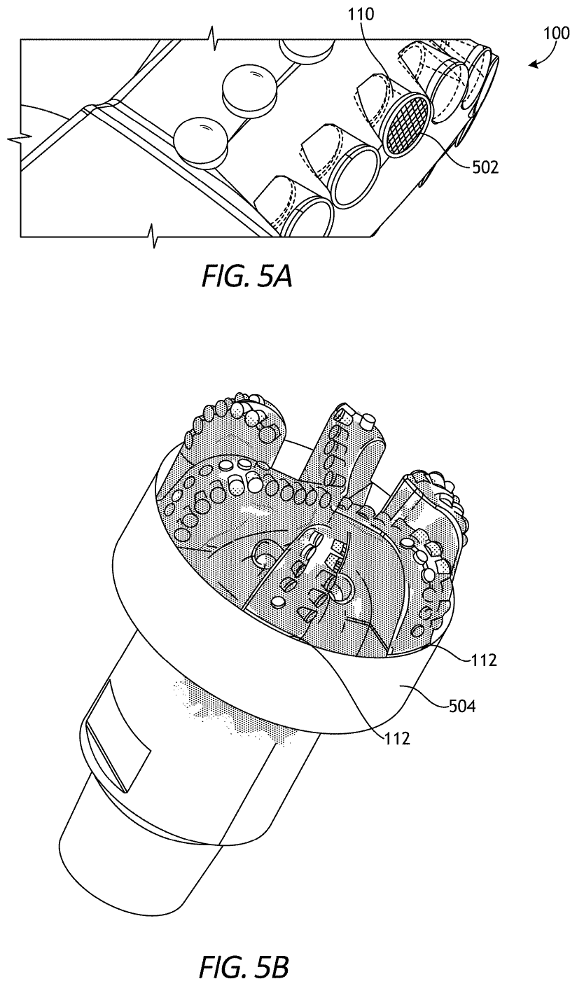

Referring to FIG. 5A, in some embodiments, a digital feature in the form of a digital plane 502 may be created and aligned with the cutter face of each cutting element 110 of the drill bit 100, and based on values obtained from the data file corresponding to the drill bit 100. As illustrated, the digital plane 502 may comprise a circle, an ellipse, or any other geometric shape sufficient to align with the corresponding cutter face of each cutting element 110.

Referring to FIG. 5B, in other embodiments, or in addition thereto, a digital feature in the form of a digital cylinder 504 may be created and aligned with the gauge pads 112 of the drill bit 100. More specifically, the digital cylinder 504 may be created based on the manufactured diameter of the drill bit 100, as obtained from the corresponding data file, or as extracted/measured from the CAD model. The digital cylinder 504 may help determine the gauge diameter measurement when undertaking wear calculations, thus helping determine the true (actual) gauge of the drill bit 100 after it exits the wellbore. This may help quantify the amount of material removed, and may also help specify if the gauge pads 112 are out of tolerance, if at all, and by what amount.

Referring again to FIG. 3, the method 300 may further include calculating the deviation between the solid model file and the scanned file at each wear part and thereby determining material removed from the wear parts of the well tool, as at 320. Once all the digital features have been created, the computer system 204 may be programmed to run a third or “volume/area calculation” programming instruction, which may be programmed into the 3D modeling and metrology software. The volume/area calculation programming instruction may be configured to retrieve nominal values that were set for the cutter dimensions (e.g., area and/or volume) of each cutting element (FIGS. 1, 4, and 5A) and the outer diameter of the bit body 102 (FIG. 1) at the gauge pads 112 (FIGS. 1, 4, and 5B). Such nominal values may be retrieved from the data file or CAD dimensions corresponding to the drill bit 100. The volume/area calculation programming instruction may then be programmed to compare the nominal values to the scanned file to quantify the area or volume removed from the wear parts, or wear scar distance at the wear parts. In some embodiments, the diamond area removed (DAR) from the cutting elements 110 and the amount of material removed at the gauge pads 112 may be determined.

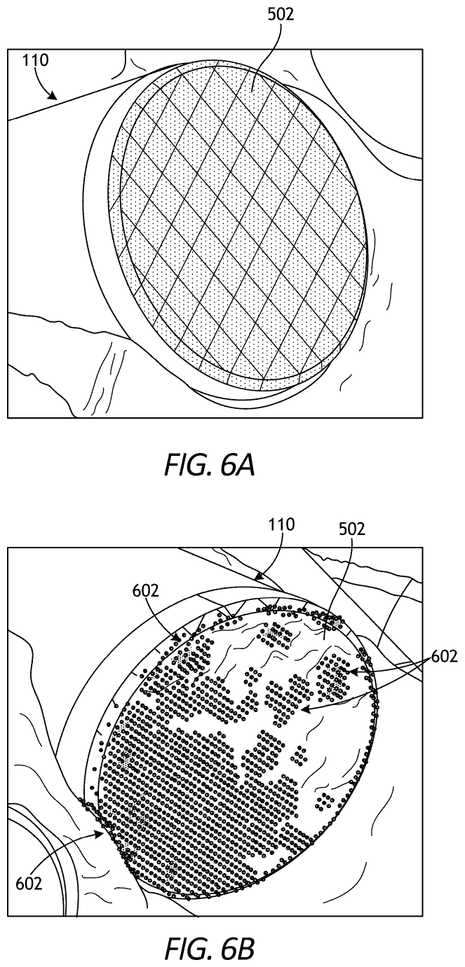

Referring to FIGS. 6A and 6B, depicted are enlarged images of an example cutting element 110 demonstrating surface area material loss, according to one or more embodiments. More specifically, FIG. 6A depicts the cutting element 110 with the digital plane 502 applied thereto and aligned with the cutting face, as generally described above. The volume/area calculation programming instruction may be programmed to use predetermined presets to measure the distance from the digital plane 502 to the actual scanned surfaces of the scanned file. The predetermined presets (e.g., alignment parameters) define at what depth to look for point clouds. This takes into account minor misalignments that can occur as well as spalling or thin layers of diamond loss. FIG. 6B depicts point cloud data points 602 where the digital plane 502 aligns with the scanned file at the cutter table. Locations on the cutter face where no point cloud data points 602 are observed represent areas where the cutter table has eroded or worn away.

The volume/area calculation programming instruction may be programmed to quantify the area of the point cloud data points 602 and assign a value to each cutting element 110. From that value, the volume/area calculation programming instruction may be programmed to calculate the DAR for each cutting element 110 and may place all measurements into comma separated variable (CSV) format as well as assign calculations in the corresponding dialogue tree. Associating the DAR values with the individual cutting elements 110 in the dialogue tree of the metrology software helps facilitate viewing and/or reporting visual annotations of the DAR values on the model within subsequently-generated reports and/or the software. As will be appreciated, similar calculations can be undertaken at the gauge pads 112 (FIGS. 1, 4, and 5B) using the digital cylinder 504 to determine how much material was removed from the outer diameter of the drill bit 100 during operation.

Referring again to FIG. 3, the method 300 may further include generating one or more reports detailing quantified wear data, as at 322. More particularly, the computer system 204 may be programmed to run a fourth or “auto-generate report” programming instruction, which may be programmed into the 3D modeling and metrology software. The auto-generate report programming instruction may be configured to generate a variety of types of reports. In some embodiments, the auto-generate report programming instruction may be programmed to produce a PDF report with a corresponding data file containing images and tabular quantified wear data for each of the cutting elements 110 (FIGS. 1, 4, and 6A-6B) listed in the data file for the drill bit 100. The PDF report may provide, among other features, color or “heat” maps of the drill bit 100, which detail where erosion occurred and its severity. In such embodiments, a legend may be provided based on pre-determined tolerances of wear severity. Moreover, calculated values for the cutting elements 110 may be placed in a table below each image for user reference.

The PDF report may further provide various images for each blade 104 (FIG. 1) and key areas of interest on the drill bit 100. More specifically, the auto-generate report programming instruction may be configured to obtain and produce still images of each blade 104. In some embodiments, the PDF report may provide gauge diameter calculations, which provide measurements on how much material was lost at or near the gauge pads 112 (FIG. 1) of the drill bit 100.

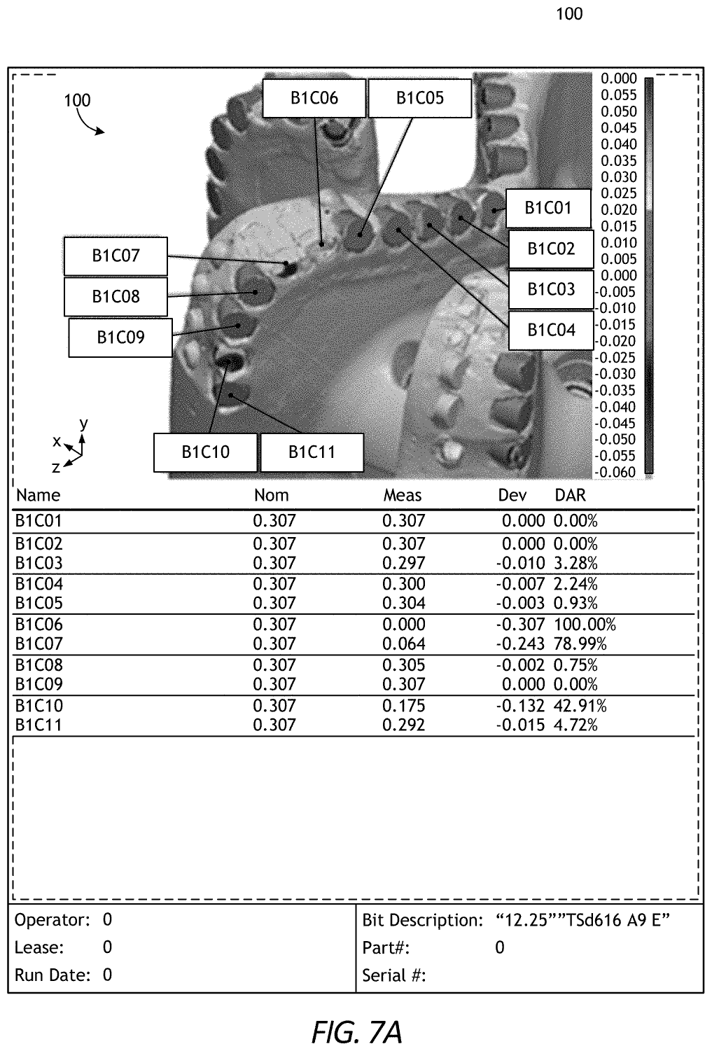

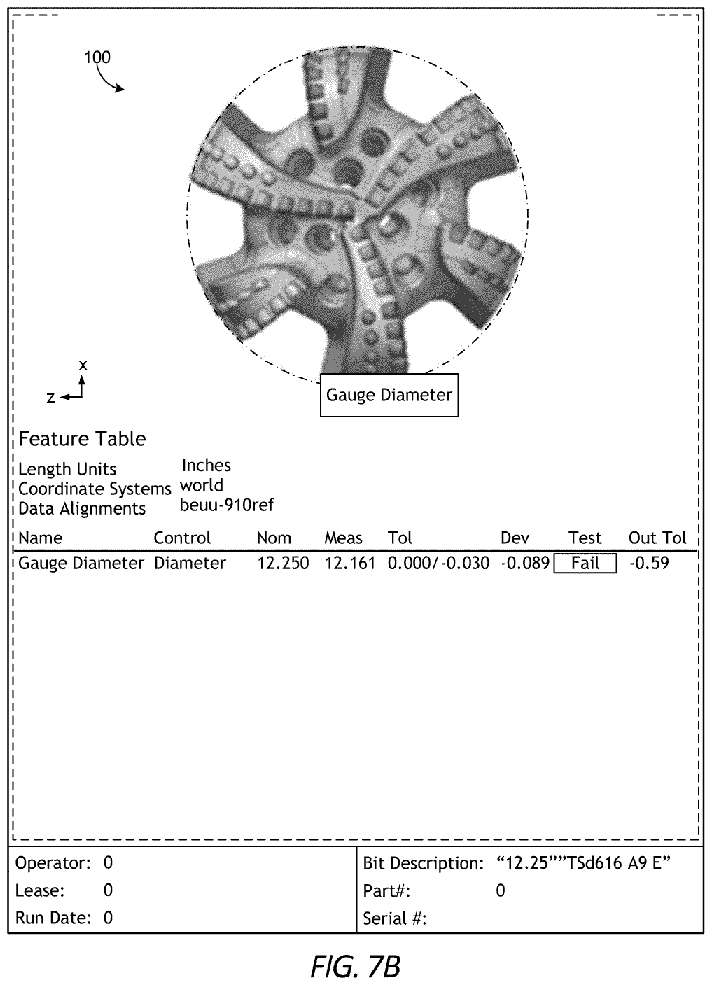

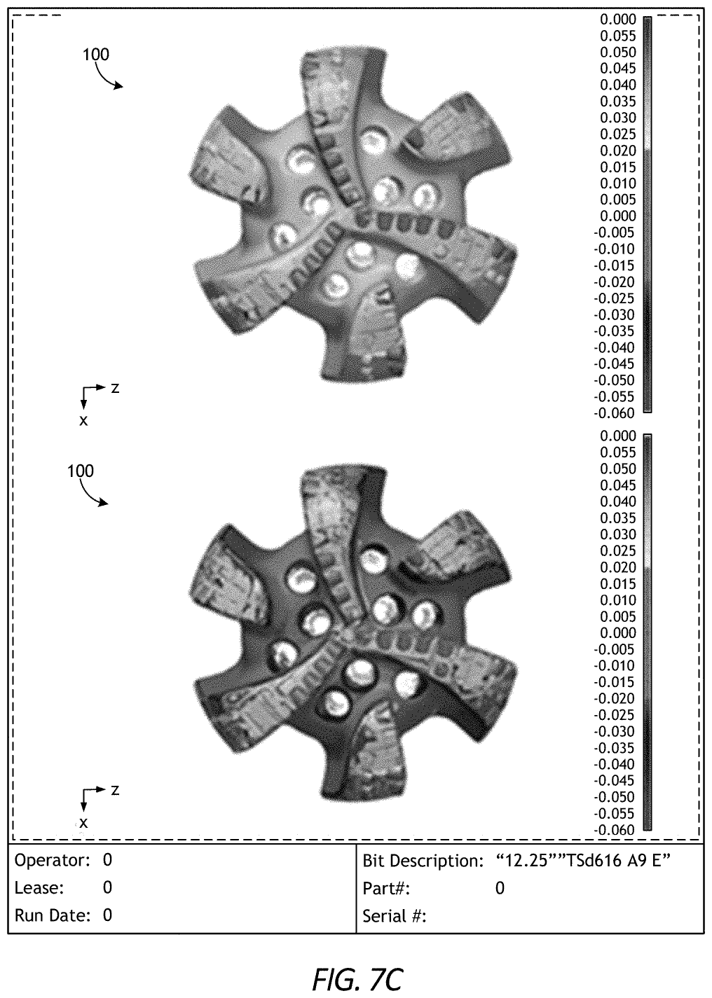

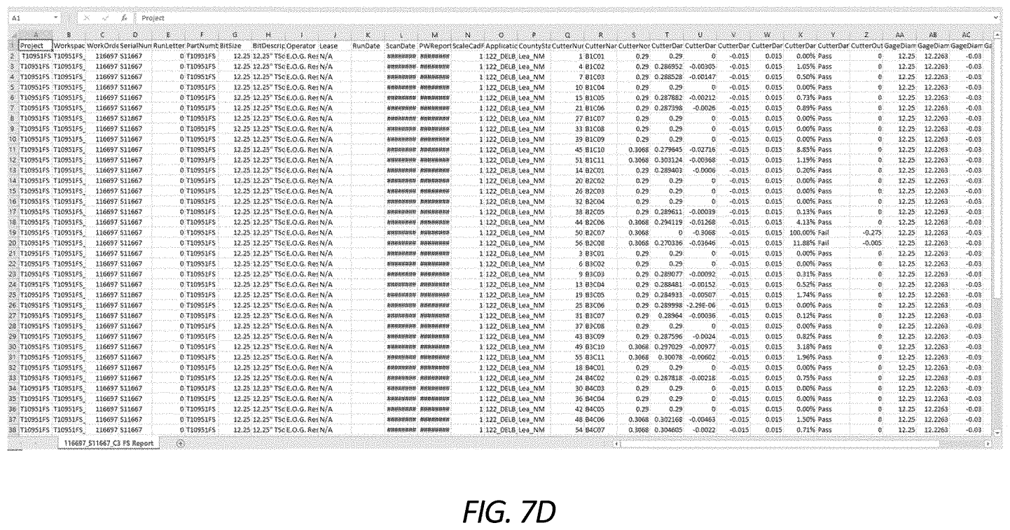

FIGS. 7A-7D depict example wear data reports that may be generated using the auto-generate report programming instruction, according to one or more embodiments. In FIG. 7A, unique annotations may be generated for each cutting element to provide details of wear data; i.e., how much material loss occurred for each individual cutting element. In some embodiments, as illustrated, the severity of material loss may be reported graphically with a color-coded graphical output, where different colors correspond to differing amounts of material loss. The report in FIG. 7A also includes tabular quantified wear data for each of the cutting elements 110. This reporting helps the operator and tool company to visually correlate the tabular wear data to the physical location across the profile of the well tool to better understand potential root causes of the wear.

In FIG. 7B, gauge diameter calculations for the drill bit 100 are provided, which provide determinations on how much material was lost at or near the gauge pads 112 (FIG. 1) of the drill bit 100. Accordingly, this report aids in visual correlation of the gauge diameter and how this measurement is being acquired.

FIG. 7C depicts a report that applies a color map overlay to images of the drill bit 100 as a visual representation of the wear and deviations being reported on the drill bit 100. As indicated above, the severity of material loss may be reported graphically and color-coded, where different colors correspond to differing amounts of material loss. This visual representation of material loss across the entire bit head can be helpful in evaluating hydraulic erosion trends to validate and/or optimize CFD modeling as well as visualizing wear patterns as related to radial location on the bit.

FIG. 7D depicts an example CSV wear report that may be generated following the presently described automated inspection process, according to one or more embodiments. The CSV wear report output (or similar tabular report) may contain large amounts of data captured during the automated inspection process including bit description, application details, nominal area values, measured area values, diamond area removed, gauge diameter, and tolerances, among many other variables/metrics. At least one advantage to having detailed inspection data in a plain text CSV file format is that the user can easily import the comprehensive dataset into many different applications and/or databases for storage and/or analysis.

Once wear data for the drill bit 100 is calculated and collected, it is contemplated herein to optimize subsequent drill bit design and/or manufacturing processes based on the wear data. More specifically, by knowing the drilling conditions the drill bit 100 undertook during operation and the resulting wear data, subsequent drill bits can be designed or manufactured to reinforce certain wear parts or regions of the bit to prolong its lifespan. Optimizing subsequent drill bit design and/or manufacturing, for instance, may entail a correlation analysis to identify volume or rock removed, cut area, weight on bit, torque on bit, distance traveled, hydraulic energy, depth of cut, formation unconfined compressive strength, mechanical specific energy, and other operation parameters. Once the wear for a specific cutting element within the drilling environment is determined, this can be used to optimize the design or cutter type for subsequent drill bits and thereby maximize performance when drilling in similar drilling environments and under similar drilling conditions.

In some embodiments, the methods described herein may include conducting an economic analysis of wear and/or wear rate for various material types to determine association between cost and performance.

In some embodiments, the methods described herein may include correlating electronic drilling recorder (EDR) data to quantified wear data to determine depth of cut and/or energy applied to the well tool. In such embodiments, the EDR data may be compared to the wear data to potentially identify optimal parameters in order to mitigate (reduce) the wear. In some embodiments, this correlation process may allow operators to determine wear rate per foot drilled. In at least one embodiment, correlating the wear rate per foot drilled may take into consideration any forces acting on the individual wear parts of the drill bit; e.g., weight on bit, torque on bit, hydraulic energy, RPM, etc. This analysis may be beneficial in helping to modify the design of the drill bit for improved performance and longevity, and/or optimize the drilling parameters to maximize bit life.

In some embodiments, a wear index may be created and applied for specific drilling applications and/or formations drilled using the drill bit 100, and thereby helping to predict wear probability. The wear index could be created once a large enough data set is obtained and correlated to specific formation drilling applications. The wear index may be obtained or determined, at least in part, by using various statistical analysis and modeling methods, such as linear regression. In such embodiments, coefficients and weights for various known downhole forces may be applied in the analysis and may be useful in predictive modeling that can estimate wear given specific changes to the design and/or materials of the drill bit 100. In at least one embodiment, the wear index could be on a scale of 1-10, but could alternatively be on a different type of scale, without departing from the scope of the disclosure. In such embodiments, increments of the wear index may be equated to certain types of drill bits used in particular drilling applications to maximize performance. Accordingly, the increments of the wear index may correspond to specific drilling applications and/or formations and may include correlation of rock strength analysis and/or unconfined compressive strength (UCS) with wear.

### Sectioned Cutters

During the repair process of drill bits (e.g., PDC bits), worn cutters are commonly detached from the cutter pocket and turned (rotated) to orient an unworn or new cutting edge toward the point of contact with the underlying rock. In such processes, worn portion(s) of the cutter are turned (rotated) down into the cutter pocket in order to avoid being directly exposed to contact with the rock being drilled. Some cutters may be turned (rotated) three or four times before scrapping the cutter, and each time the cutter is turned, an undamaged (sharp) cutter edge is exposed and aligned with the point of contact for a subsequent run downhole. This process can save money by utilizing each cutter to its maximum potential.

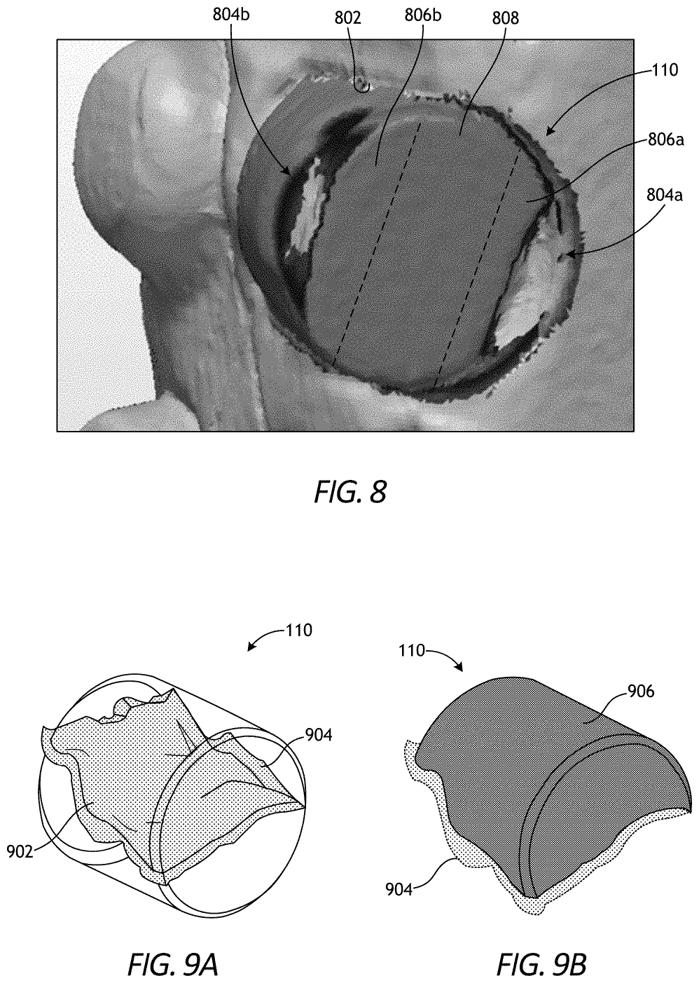

Referring to FIG. 8, illustrated is an enlarged scanned view of a worn cutter 110 seated within a corresponding cutter pocket 802. As illustrated, the cutter 110 has a first worn edge 804a and a second worn edge 804b, thus evidencing that the cutter 110 has been used in at least two runs and detached and rotated within the cutter pocket 802, as generally described above. As a result, the first worn edge 804a is oriented away from the point of contact with the rock and the second worn edge 804b is oriented toward the point of contact.

It may be desired to determine the wear and/or diamond area removed (DAR) from the cutting element 110 during the last operation (e.g., the last run or trip downhole). To do this, an operator may follow the steps of the method 300 of FIG. 3, but the resulting wear measurements obtained using the method 300 would be skewed for the last run since it would determine wear and/or DAR for both worn edges 804aa,b, whereas the wear and/or DAR for the second worn edge 804b is only desired.

According to embodiments of the disclosure, the CAD file of the cutting element 110 may be digitally divided into two or more sections that include corresponding two or more cutting edge portions of the cutting element 110 to be analyzed for wear. In the illustrated embodiment, the cutting element 110 is digitally divided into a first section 806a and a second section 806b, where the first section 806a encompasses the first worn edge 804a and the second section 806b encompasses the second worn edge 804b. The first section 806a may be characterized as an “unexposed” section since the first worn edge 804a is oriented away from contact with the rock, whereas the second section 806b may be characterized as an “exposed section” since the second worn edge 804a is oriented toward contact with the rock. In this embodiment, the first and second sections 806a,b comprise sections corresponding to approximately 30% of the surface area of the cutter face 808. In other embodiments, however, the sections 806a,b may comprise other surface area percentages of the cutter face 808, such as up to 50% each. In yet other embodiments, the cutting element 110 may be digitally divided into more than two sections, such as three or four sections. In embodiments with four sections, the sections may each encompass 25% of the surface area of the cutter face 808, for example.

In this embodiment, step 320 of the method 300 of FIG. 3 may be modified and otherwise further include calculating the deviation between the solid model file and the scanned file at an exposed section of the cutting element 110, such as the second section 806b, while disregarding (ignoring) the unexposed section(s), such as the first section 806a. As a result, the determination of material removed from the cutting element 110 will be isolated to only the second section 806b, which includes the second worn edge 804b, while any wear present in the first section 806a, including the first worn edge 804a, will be omitted from the resulting wear calculation. As will be appreciated, this will generate wear calculations for the cutting element 110 corresponding to the most recent run, while omitting wear (losses) on the cutting element 110 resulting from any prior runs, which would skew the overall data.

### Correlating Wear to Downhole Drilling Dynamics

It is contemplated herein to install various sensors in downhole well tools to obtain data related to the well tool during downhole operation, and correlate that data to subsequent observed wear. More particularly, one or more sensors may be installed in the drill bit 100 and designed to monitor (detect) various downhole drilling dynamics including, but not limited to, vibration, acceleration, shock, orientation, temperature, weight on bit, pressure, or any combination thereof. This data may be tracked to better understand the specific dynamics experienced by the drill bit 100 during operation.

However, such data may also be correlated to the wear experienced on the drill bit 100 during operation to better understand the effect of drilling dysfunctions on cutter wear. This analysis may help an operator optimize drilling parameters, optimize parameter road mapping to mitigate tool dysfunction and wear, aid in bit and/or cutter design, and aid in material selection and optimization to mitigate tool dysfunction and/or wear.

### Automating the IADC Dull Grading System

As discussed herein, the International Association of Drill Contractors (IADC) developed and uses a dull bit grading system that provides a standardized protocol for evaluating drill bits and classifying drill bit wear/damage. In the IADC dull grading process, an evaluator visually inspects the dull bit and manually quantifies the observed wear using a standardized eight-field code; i.e., 0 to 8 scale, where 0=no wear, and 8=effective cutting structure completely worn away. The current IADC dull grading system divides the bit into the inner ⅔ diameter of the bit body and the outer ⅓ of the bit body and assigns an average of the wear sustained on the cutters located in the inner ⅔ and the outer ⅓ to the 0 to 8 scale.

According to embodiments of the present disclosure, the basic evaluation principles provided by the IADC dull grading process may be automated using the methods described herein. In the presently disclosed embodiments, the computer system 204 may be programmed divide the bit body 102 (FIG. 1) of the drill bit 100 (FIG. 1) into two or more radial sections extending radially outward from the centerline 108 (FIG. 1) of the bit body 102. In some embodiments, two radial sections may be identified similar to the current IADC methodology, such as the inner ⅔ diameter of the bit body 102 and the outer ⅓ of the bit body 102. In other embodiments, however, other fractions of gauge diameter may be identified extending from the centerline 108. In yet other embodiments, more than two radial sections extending from the centerline 108 may be identified, without departing from the scope of the disclosure.

The average wear of the cutting elements 110 located within each identified radial section may then be determined in accordance with the wear calculation methods described herein, thus providing a percent diamond area removed or “% DAR”. The % DAR for each identified radial section may then be correlated with an industry standard dull grading system, such as the IADC system or another system. In such embodiments, the % DAR for each identified radial section may be applied to the IADC 0 to 8 scale and assigned a number between 0 and 8, depending on the resulting (calculated) % DAR. In other embodiments, however, the % DAR may be applied to any other grading scale system, without departing from the scope of the disclosure.

### Failure Mode Classification

While understanding the amount of wear sustained is critical in well tool (e.g., drill bit) optimization, understanding the way the wear was ultimately sustained during operation may also be important. By evaluating the characteristics of the wear, such as geometry, magnitude, direction, etc., it may be possible to classify the damage into specific failure modes and thereby facilitate a root cause analysis of the damage. Wear parts can fail due to a variety of root causes, for example, such as abrasion, thermal degradation, mechanical overloading, erosion, corrosion, manufacturing defects, oxidation, or any combination thereof.

FIG. 9A is an isometric view of an example cutting element 110 that graphically depicts sustained failure damage. More specifically, FIG. 9A depicts a failure surface 902 indicating where a large portion of the cutting element 110 was extracted during operation by reason of failure. According to embodiments of the present disclosure, one or more digital features 904 may be generated to overlay the failure surface 902 and thereby generally follow the surface (contour) of the damage. Similar to the digital features described above with reference to FIGS. 5A-5B, the digital feature(s) 904 applied to the failure surface 902 may constitute computer-generated surfaces overlaid onto the scanned data of the well tool. Depending on the geometry of the resulting digital feature(s) 904, an appropriate failure mode may then be assigned to the worn part. Example failure modes include, but are not limited to, smooth wear, thermal-mechanical wear, cracking, chipping, spalling, tangential fracture / break, delamination, etc.

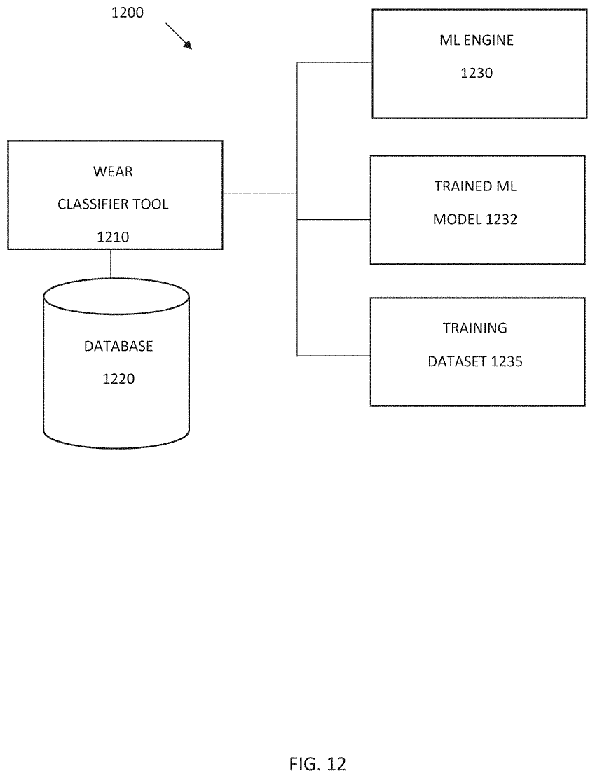

The computer system 204 may also be programmed and otherwise trained to use machine learning and neural networks to aid in automated failure analysis and classification for individual wear parts. Failure mode classification could be achieved using various forms of artificial intelligence approaches. In example applications using machine or deep learning, example images of common (or less-common) failure modes may be used to train an artificial intelligence model on how to classify the failure modes accurately. Well tool wear classification systems and methods using machine learning are described in further embodiments below with respect to FIGS. 12-16.

In other applications, or in addition thereto, such as in rule-based artificial intelligence systems, the characteristics of the failure modes may be defined within coding in order for the computer system 204 to properly assign a failure classification.

In some embodiments, the resulting digital feature(s) 904 applied to the failure surface may then be compared to the CAD model of the wear part in order to model the missing portion of the wear part. FIG. 9B, for example, shows a graphical representation 906 of the missing part (material) from the cutting element 110 of FIG. 9A. The graphical representation 906 may prove advantageous in helping to determine the geometry and amount (volume) of material lost from the cutting element 110.

### Computational Fluid Dynamics

Upon calculating deviation between the solid model file and the scanned file at the digital features for the wear parts, and determining material removed from the wear parts of the well tool, it is also contemplated herein to compare (correlate) the determined wear data to computational fluid dynamics (CFD) modeling. Correlating wear to CFD results, in this instance flow lines, enables an operator (user) to confirm if the damage being sustained is related in some way to drilling fluid circulation, which may result in erosion and/or corrosion. In some embodiments, the CFD modeling may be generated from an add-in within CAD modeling/design software packages (e.g., SolidWorks).

CFD simulations can have a multitude of variables and/or parameters that an operator (user) can adjust to best fit the real world scenario or application. It is often difficult to determine the accuracy of the simulations, thereby leaving much room for ambiguity in selecting the most appropriate parameters to use during simulations. Having highly precise wear quantification, however, provides a much needed feedback system for the CFD analysts to evaluate (or validate) the accuracy of their simulations and adjust the parameters of the models as needed to better match the actual or observed effects of fluids on the well tool. Accordingly, comparing the wear data to CFD modeling may prove advantageous in helping to validate CFD modeling.

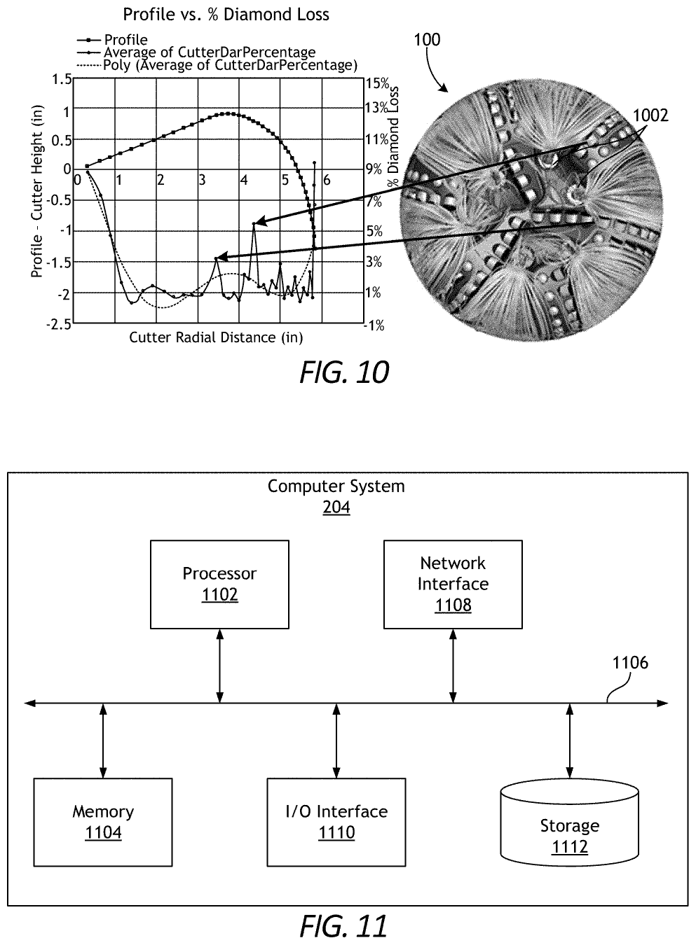

FIG. 10 depicts an example of observed CFD flow lines across a well tool (e.g., the drill bit 100) being correlated to cutting element wear, according to one or more embodiments. In the illustrated example, flow lines are observed traveling (flowing) across erosion-prone (relative to the diamond table) cutting element substrates on the CFD modeling, and a corresponding spike in % DAR is recorded in the adjoining graph. If the erosion-prone substrate sustains erosion, the diamond table of the cutting element may be left unsupported and is more likely to fail. With this understanding (data), an operator (user, designer, manufacture, etc.) may be able to adjust one or more parameters of the drill bit 100 to help prevent erosion. In some embodiments, for instance, the orientation of nozzles 1002 in the drill bit 100 may be adjusted to reduce the hydraulic flow traveling across the cutting elements, which may reduce the risk of fluid-related damage on the cutting elements. FIG. 10 provides an example of this relationship and phenomenon. Accordingly, in some embodiments, wear patterns identified on the drill bit 100 may be correlated to CFD modeling to optimize hydraulic layouts of the drill bit 100 and thereby minimize fluid erosion.

FIG. 11 is a schematic diagram of the computer system 204 of FIG. 1. As shown, the computer system 204 includes one or more processors 1102, which can control the operation of the computer system 204. “Processors” are also referred to herein as “controllers.” The processor(s) 1102 can include any type of microprocessor or central processing unit (CPU), including programmable general-purpose or special-purpose microprocessors and/or any one of a variety of proprietary or commercially available single or multi-processor systems. The computer system 204 can also include one or more memories 1104, which can provide temporary storage for code to be executed by the processor(s) 1102 or for data acquired from one or more users, storage devices, and/or databases. The memory 1104 can include read-only memory (ROM), flash memory, one or more varieties of random access memory (RAM) (e.g., static RAM (SRAM), dynamic RAM (DRAM), or synchronous DRAM (SDRAM)), and/or a combination of memory technologies.

The various elements of the computer system 204 can be coupled to a bus system 1106. The illustrated bus system 1106 is an abstraction that represents any one or more separate physical busses, communication lines/interfaces, and/or multi-drop or point-to-point connections, connected by appropriate bridges, adapters, and/or controllers. The computer system 204 can also include one or more network interface(s) 1108, one or more input/output (IO) interface(s) 1110, and the one or more storage device(s) 812.

The network interface(s) 1108 can enable the computer system 204 to communicate with remote devices, e.g., other computer systems, over a network, and can be, for non-limiting example, remote desktop connection interfaces, Ethernet adapters, and/or other local area network (LAN) adapters. The IO interface(s) 1110 can include one or more interface components to connect the computer system 204 with other electronic equipment. For non-limiting example, the IO interface(s) 1110 can include high-speed data ports, such as universal serial bus (USB) ports, 1394 ports, Wi-Fi, Bluetooth, etc. Additionally, the computer system 204 can be accessible to a human user, and thus the IO interface(s) 1110 can include displays, speakers, keyboards, pointing devices, and/or various other video, audio, or alphanumeric interfaces.

The storage device(s) 1112 can include any conventional medium for storing data in a non-volatile and/or non-transient manner. In some aspects, the storage device(s) 1112 may be the same as the storage device 138 of FIG. 1. The storage device(s) 1112 can hold data and/or instructions in a persistent state, i.e., the value(s) are retained despite interruption of power to the computer system 204. In at least one aspect, the database 136 of FIG. 1 may be located on the storage device(s) 1112. The storage device(s) 1112 can include one or more hard disk drives, flash drives, USB drives, optical drives, various media cards, diskettes, compact discs, and/or any combination thereof and can be directly connected to the computer system(s) 204 or remotely connected thereto, such as over a network. In an exemplary embodiment, the storage device(s) 1112 can include a tangible or non-transitory computer readable medium configured to store data, e.g., a hard disk drive, a flash drive, a USB drive, an optical drive, a media card, a diskette, a compact disc, etc.

The elements illustrated in FIG. 8 can be some or all of the elements of a single physical machine. In other embodiments, however, and as mentioned above, the computer system 204 may alternatively include two or more computers or physical computing machines networked together or otherwise capable of communicating one with the other to achieve a common goal. In addition, not all of the illustrated elements need to be located on or in the same physical machine. Exemplary computer systems include conventional desktop computers, workstations, minicomputers, laptop computers, tablet computers, personal digital assistants (PDAs), and mobile phones, and the like.

The computer system 204 can include a web browser for retrieving web pages or other markup language streams, presenting those pages and/or streams (visually, aurally, or otherwise), executing scripts, controls and other code on those pages/streams, accepting user input with respect to those pages/streams (e.g., for purposes of completing input fields), issuing

HyperText Transfer Protocol (HTTP) requests with respect to those pages/streams or otherwise (e.g., for submitting to a server information from the completed input fields), and so forth. The web pages or other markup language can be in HyperText Markup Language (HTML) or other conventional forms, including embedded Extensible Markup Language (XML), scripts, controls, and so forth. The computer system 204 can also include a web server for generating and/or delivering the web pages to client computer systems.

In an exemplary embodiment, the computer system 204 can be provided as a single unit, e.g., as a single server, as a single tower, contained within a single housing, etc. The single unit can be modular such that various aspects thereof can be swapped in and out as needed for, e.g., upgrade, replacement, maintenance, etc., without interrupting functionality of any other aspects of the system. The single unit can thus also be scalable with the ability to be added to as additional modules and/or additional functionality of existing modules are desired and/or improved upon.

The computer system 204 can also include any of a variety of other software and/or hardware components, including by way of non-limiting example, operating systems and database management systems. Although an exemplary computer system is depicted and described herein, it will be appreciated that this is for the sake of generality and convenience. In other embodiments, the computer system may differ in architecture and operation from that shown and described here.

Well Tool Wear Classification using Machine Learning

FIG. 12 is a diagram of a well tool wear classification system 1200 with machine learning, according to one or more embodiments. System 1200 includes a wear classifier tool 1210 coupled to a database 1220 and a machine learning (ML) engine 1230. ML engine 1230 is further coupled to a trained ML model 1232 and training dataset 1235. Wear classifier tool 1210 can also be coupled to trained ML model 1232 and training dataset 1235. Database 1220 can be used to store scanned images, sensor data, well tool data, historical data, live sensor data and other types of data that can used for training or inference in the operation ML engine 1230. Scanned images stored in database 1220 may include digital 2D image data, electronic drilling recorder (EDR) data and 2D images of various failure modes. Database 1220 is an electronic collection of data and can be stored in computer-readable memory locally or remotely from wear classifier tool 1210.

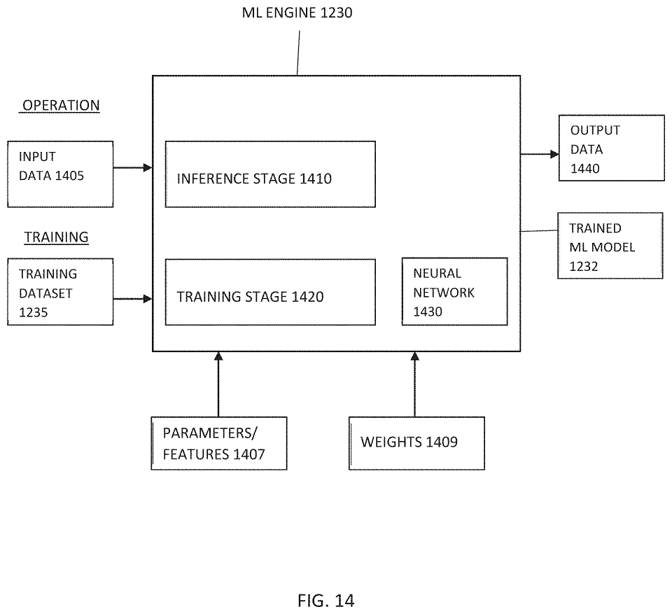

System 1200 operates to classify wear data for a well tool using machine learning. Wear classifier tool 1210 controls the wear classification of wear data for the well tool. Wear classifier tool 1210 controls the loading of training data into training dataset 1235. Wear classifier tool 1210 controls the operation of ML engine 1230 in training and inference stages, and can access trained ML model 1232. Wear classifier tool 1210 retrieves from and stores data in database 1220. Wear classifier tool 1210 further receives output from ML engine 1230. ML engine 1230 applies machine learning using trained ML model 1232 and training dataset 1235. The operation of system 1200 and its components are described further below with respect to process 1300 and examples in FIGS. 14-16. In embodiments, system 1200 can be coupled with scanning system 200 of FIG. 2 or scanning system 1700 of FIG. 17.

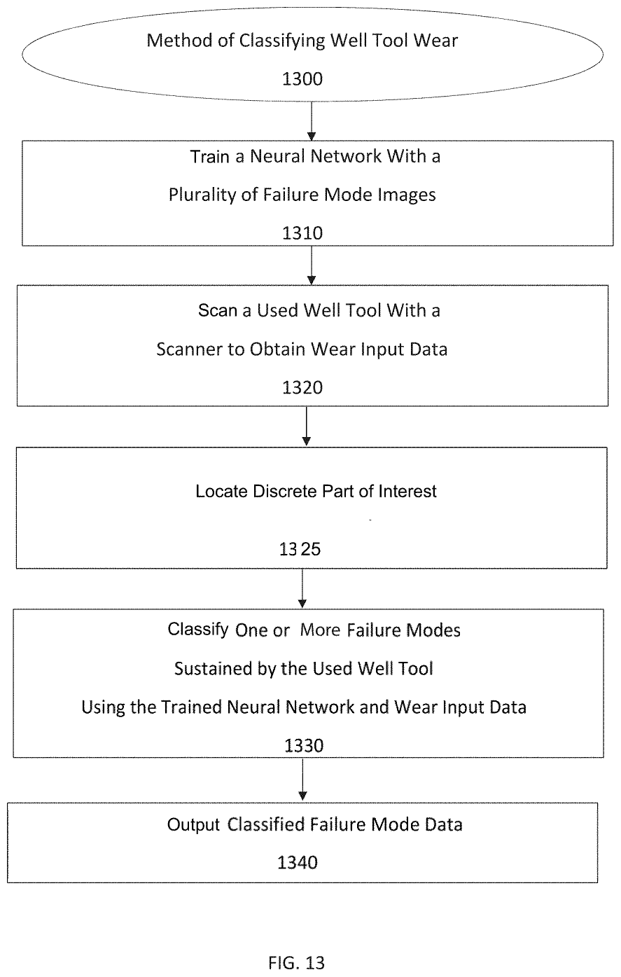

FIG. 13 is a process flow diagram of an example method for classifying a well tool 1300, according to one or more embodiments. In step 1310, a neural network is trained with a plurality of failure mode images to obtain a trained neural network (also called a model). For example, wear classifier tool 1210 (FIG. 12) can upload training data comprised of failure mode images and labels associated with classification types of the failure mode images to form training dataset 1235.

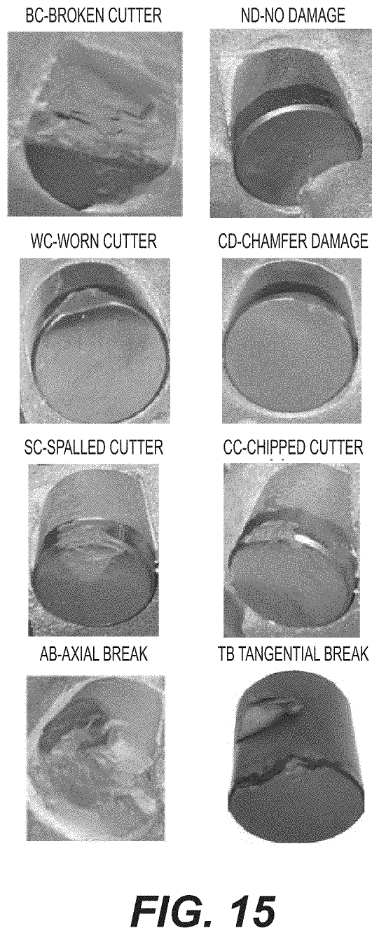

Referring briefly to FIG. 15, an example set of failure mode images for cutter failure modes for a cutting element that can be used as training data is shown. These types of failure modes (shown from left-to-right and then down) are BC-Broken Cutter, ND—No Damage, WC—Worn Cutter, CD—Chamfer Damage, SC—Spalled Cutter, CC—Chipped Cutter, AB—Axial Break, and TB—Tangential Break.

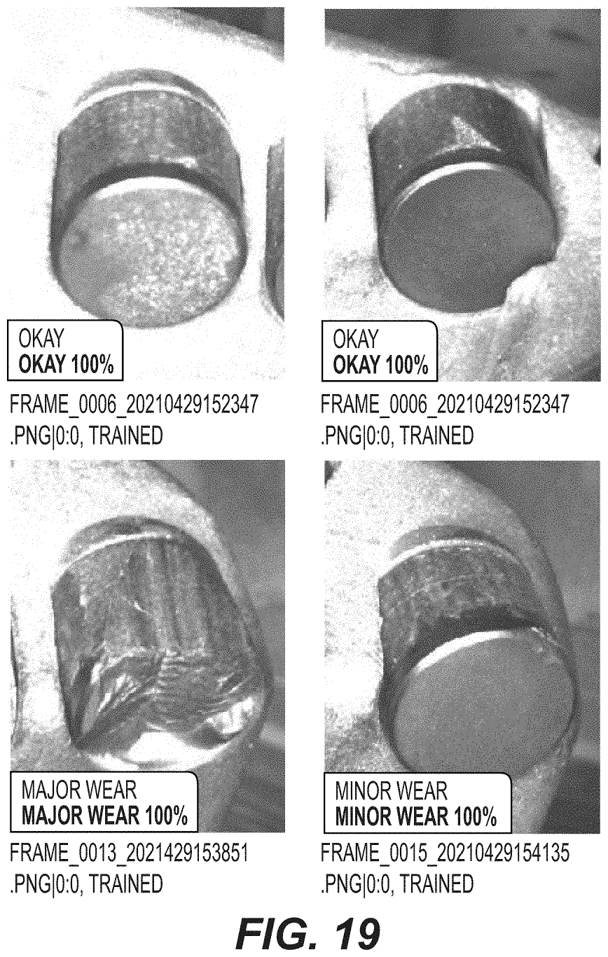

In one embodiment, image data showing different states of wear in different failure modes is used in training dataset 1235. FIG. 19 shows four example images of cutting elements for use in a training dataset 1235. The cutting elements are disposed in a substrate. For illustration here, images are overlaid with associated wear for particular cutting elements. Image (top left) shows a first cutting element determined with about 100% confidence to be in a condition

(“OK”) with no or little wear. Image (top right) shows a second cutting element determined with about 100% confidence to be in a condition (“OK”) with no or little wear. Image (lower left) shows a third cutting element determined with about 100% confidence to be in a condition with major wear. Image (lower right) shows a fourth cutting element determined with about 100% confidence to be in a condition with minor wear.

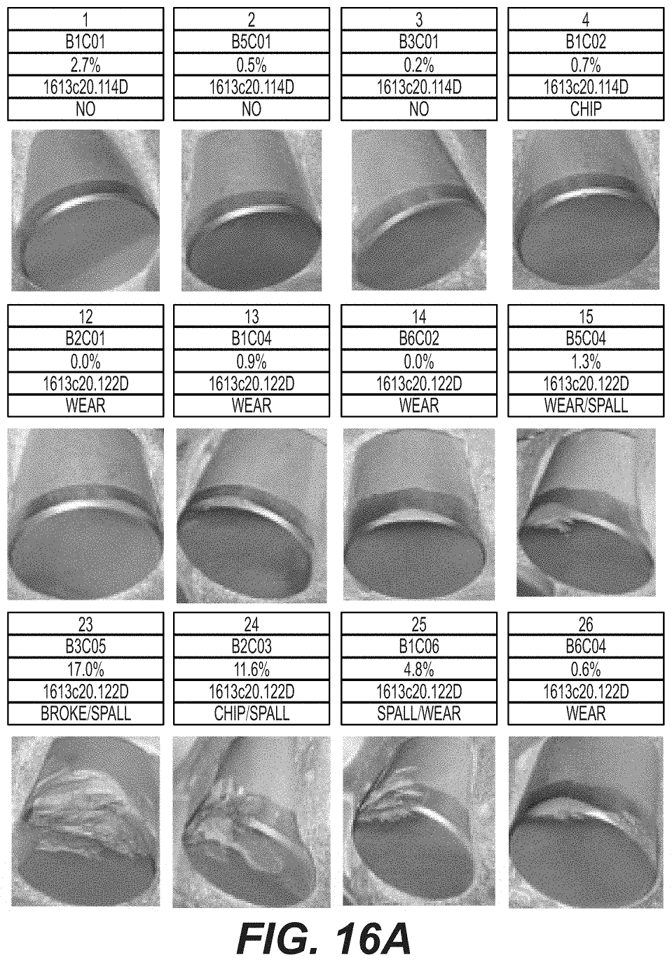

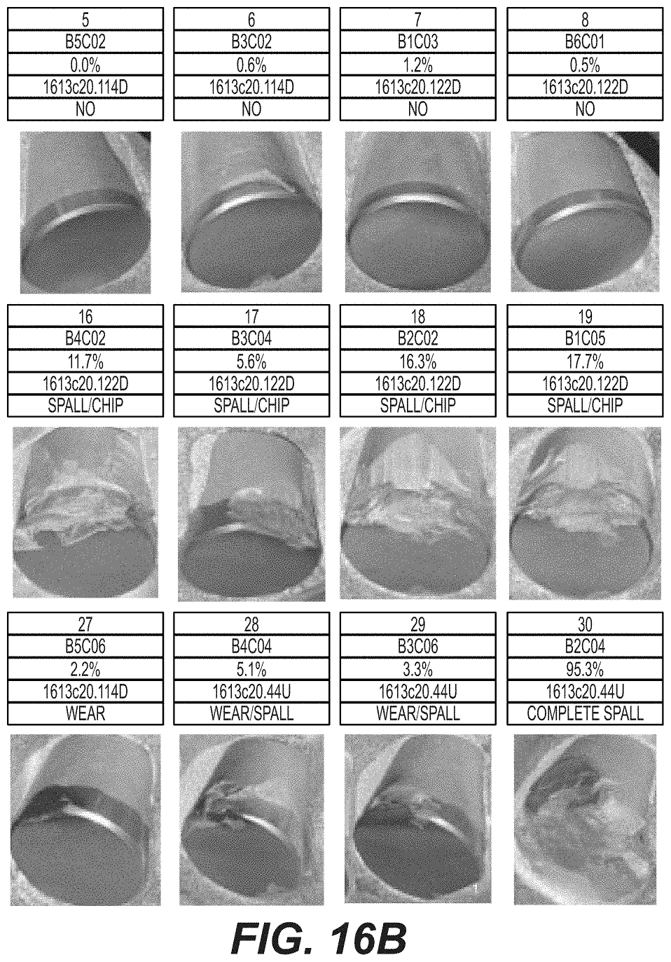

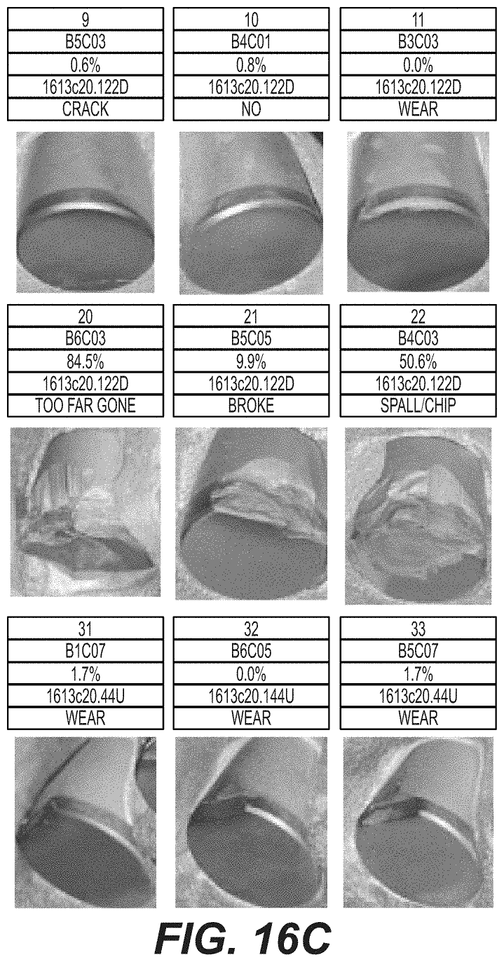

In addition to image data, other types of data and data sources may also be used as training data. This can include historical data and live sensor data. For example, and with reference to FIGS. 16A-16C, examples of automated radial position reporting for different cutting elements including classified failure mode and wear quantification data are shown. FIGS. 16A-16C illustrate visual reporting output of the individual cutter images, cutter position, cutter type, wear (DAR from 3D scanning) and failure mode (from 2D ML output). Radial reporting data fields along with values and thresholds for classification of wear by cutting elements can be used. Patterns of wear among cutting elements and their relative position on a drill bit can also be used as training data for multiple failure mode classification and/or for root cause classification of the wear trends. For instance, increased wear severity along with load related failure mechanisms in the inner or middle (cone or nose) portions of the bit profile would be indicative of axial overloading such as excessive weight on bit and/or bit bounce. Whereas increased wear severity along with load related failure mechanisms towards the outer diameter (OD) of the bit (shoulder and gauge) would be indicative of lateral and/or torsional overload events such as experienced with bit whirl and/or stick-slip.

Referring again to FIG. 13, in step 1320 a used well tool such as drill bit 100 is scanned. One or more cameras or other sensors that capture wear input data can be used. In embodiments, drill bit 100 may be scanned by scanning system 200 of FIG. 2 or scanning system 1700 of FIG. 17. In embodiments, scanner 202 may be used to capture 2D or 3D images of drill bit 100 as described above.

In further examples, camera 1702 and/or a 3D scanner 1704 may be used to capture may be used to capture 2D or 3D images of drill bit 100 respectively. For example, as shown in FIG. 17, drill bit 100 may be loaded onto a stand 1706. A first robotic arm 1704 controlled by computer system 204 can be operated to move camera 1702 relative to the drill bit 100 to scan drill bit 100 and capture a set of scanned images of drill bit 100 and its cutter elements.

Also, once 2D scanning is complete the drill bit can also be moved to stand 1716 to perform 3D scanning. A second robotic arm 1714 controlled by computer system 204 can be operated to move 3D scanner 1712 relative to the drill bit 100 to scan drill bit 100 and capture a set of scanned images and distance data (3D images) of drill bit 100 and its cutter elements.

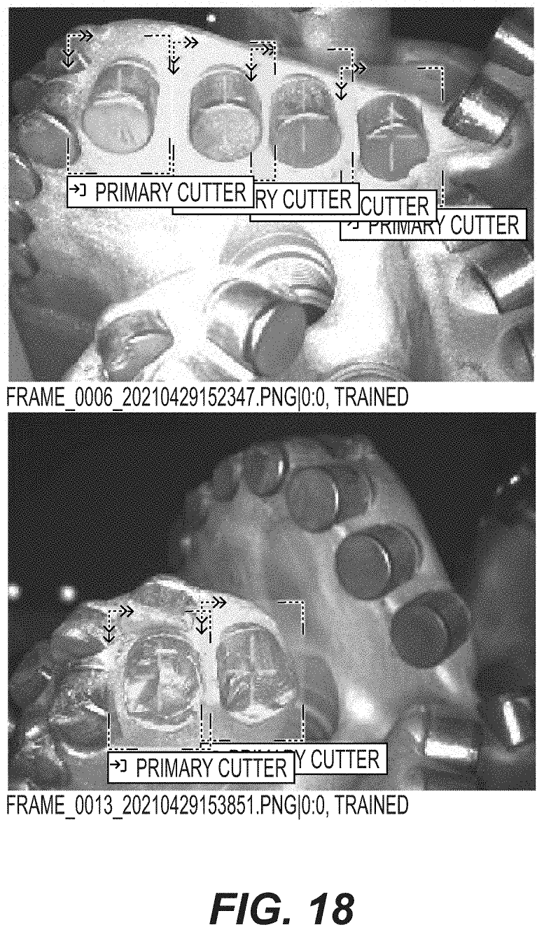

In step 1325, a discrete part of interest is located within an image captured in a scan in step 1320. The part of interest, for example, can be a region corresponding to a cutting element desired to be classified for wear. FIG. 18 shows two example images output by wear classifier tool 1210 that show locations of cutting elements (i.e., primary cutters) found by tool 1210 in step 1325. The cutting elements are disposed in a substrate. The image on the top half in FIG. 18 shows regions of an image that corresponds to four primary cutter elements. The image on the bottom half in FIG. 18 shows regions of an image that corresponds to two primary cutter elements.

In step 1330, one or more failure modes sustained by the used well tool are classified using the trained neural network and the captured wear input data. For example, wear classifier tool 1210 (FIG. 12) can call ML engine 1230 (FIG. 12) to classify a failure mode using the trained ML model 1232 (FIG. 12) and the captured wear input data stored in database 1220 (FIG. 12) or other memory for input to the ML engine 1230. ML engine 1230 applies the input data to the trained ML model 1232 and obtains output data representative of a classification of a failure mode for the captured wear input data.

In step 1340, classified failure mode data is output. For example, wear classifier tool 1210 receives the output data from ML engine 1230 and outputs classified failure mode data for display, storage, or transmission. For example, wear classifier tool 1210 can output for display an image of the scanned used well tool along with the associated classification failure mode data. Wear classifier tool 1210 can also include an alert generator to generate an alert for a user for certain types of failure modes. As shown in an embodiment in FIG. 14, ML engine 1230 includes an inference stage 1410, a training stage 1420, and a neural network 1430. During training step 1310 (FIG. 13), training stage 1420 receives training dataset 1235 and applies it to neural network 1430 to obtain a set of candidate ML models. Training stage 1420 then selects a ML model from the set of candidate ML models for output as the trained ML model 1232. One or more parameters or features 1407 and weights 1409 may also be applied to training stage 1420. For example, training stage 1420 may select the model from the set of candidate ML models which minimizes a loss function using weights 1409 and parameters 1407. Neural network 1430 can be a convolutional neural network (CNN) such as a multi-layer CNN having feature detection and classification. A multi-layer CNN may include a number of convolution layers preceeding sub-sampling (pooling) layers coupled to ending layers made up of fully connected (FC) layers.

Training stage 1420 can select a trained multi-layer CNN and associated weights 1409 which minimize a loss function or obtain other optimization. Supervised learning or unsupervised learning with the multi-layer CNN can be used in the training. Parameters or features 1407 and one or more weights 1409 can also be applied during training to the training stage 1420.

Inference stage 1410 receives input data 1405 and applies trained model ML 1232 to determine output data 1440. Parameters or features 1407 and one or more weights 1409 can also be applied during to the inference engine 1410 to further tailor the operation of inference stage 1410. In embodiments, ML engine 1230 applies deep learning. During training to obtain trained ML model 1232, parameters are determined based on characteristics of the training data learned or obtained during the training process rather than a predetermined rule and predetermined parameter based training. Weights based on frequency and/or chronology, e.g. most recent and frequently observed failure modes receive higher weight, may also be learned within deep learning training.

In operation in step 1330, wear data captured in step 1320 can be used as input data 1405. One or more scanned image files of a drill bit in a used well tool can be used. In another example, other data can also be input to inference engine 1430 along with scanned image files to further classification such as image type (2D or 3D), scanner type, sensor information, distance to wear surface, or wear tool information, such as, age, number of cutting elements, and cutting element arrangement or pattern.

Inference stage 1410 applies the trained ML model 1232 to the input data 1405. Trained ML model 1232 extracts features and classifies the input data 1405 to obtain an output array of data. For example the trained ML model can have a trained multi-layer CNN that applies kernels to input image classification. The output array of data from the multi-layer CNN represents a failure mode.

Parameters 1407 can include additional data pertinent to feature extraction and classification. Parameters 1407 can be used such as, 2D or 3D image type, distance to a captured wear tool surface, or radial position of image. Weights 1409 can be applied to the trained ML model 1232 to further govern inference operation.

Output data 1440 can be an output array of data representative of a classification of a failure mode for the captured wear input data 1405. For example, as shown in FIG. 15, the output array of data can include data identifying one or more cutter failure modes for cutting elements in the drill bit. These types of failure modes can include BC—Broken Cutter, ND—No Damage, WC—Worn Cutter, CD—Chamfer Damage, SC—Spalled Cutter, CC—Chipped Cutter, AB—Axial Break, or TB—Tangential Break. In addition, failure modes could be isolated to the tungsten carbide substrate portion of the PDC cutter to include failure modes erosion, corrosion, rubbing and heat checking. These failure modes are illustrative and not intended to be limiting.

Other types of failure modes can be classified depending upon a particular application, tool, and wear being inspected.

In further embodiments, output classification modes from inference stage 1410 also include patterns of wear among cutting elements and their relative position on a drill bit and predictive information on whether a drill bit of a well tool needs to be repaired or replaced.

Further examples of training data, input and output data and labels, and parameters and weights and classifications are described below.

### Further Examples and Use Cases

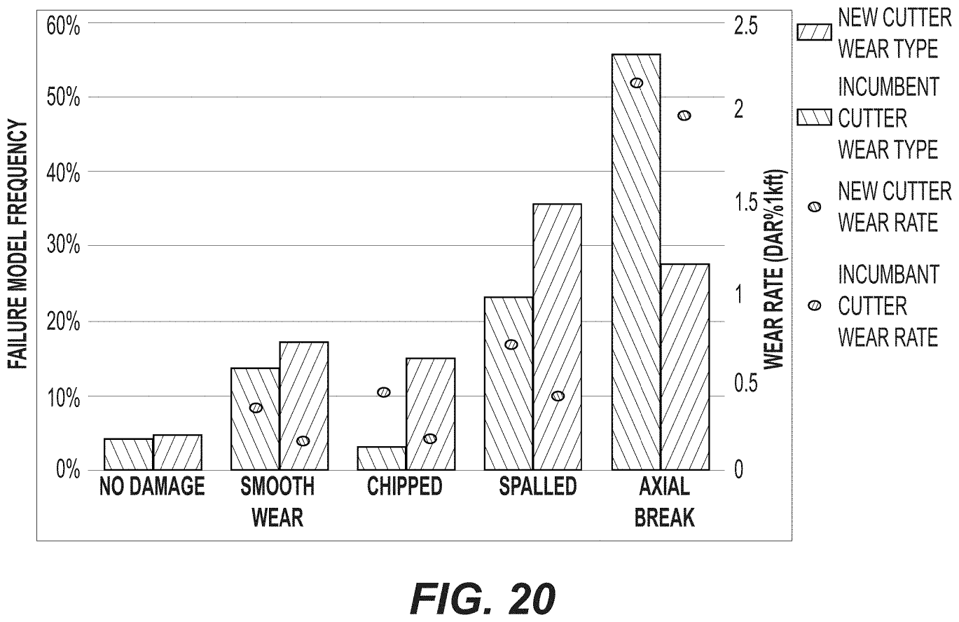

FIG. 20 is graph that shows results of an example case study for new and incumbent cutters tested in a drill bit analyzed by wear classifier tool 1210 according to an embodiment. In this case study, output data was obtained from system 1200 using example 3D scanning metrology and 2D ML models to evaluate failure mode frequency and wear rate for different new and incumbent cutters tested in drill bits. The graph in FIG. 20 shows different wear types determined for new and incumbent cutters plotted along the horizontal axis with failure mode frequency for wear type (shown on the left vertical axis) and wear rate (diamond area removed (DAR) %/footage drilled, shown on the right vertical axis).

The scanner assembly of FIG. 17 is illustrative and not intended to be limiting. Other configurations may be used to scan a well tool for wear. For example, in an embodiment, camera 1702 and 3D scanner 1712 may be attached to the same robotic arm 1704 to obtain data in parallel or in series. Furthermore, the acquisition of data by camera 1702 and/or 3D scanner 1712 could be accomplished manually, without the need for a robotic arm.

Substrate Damage Classification

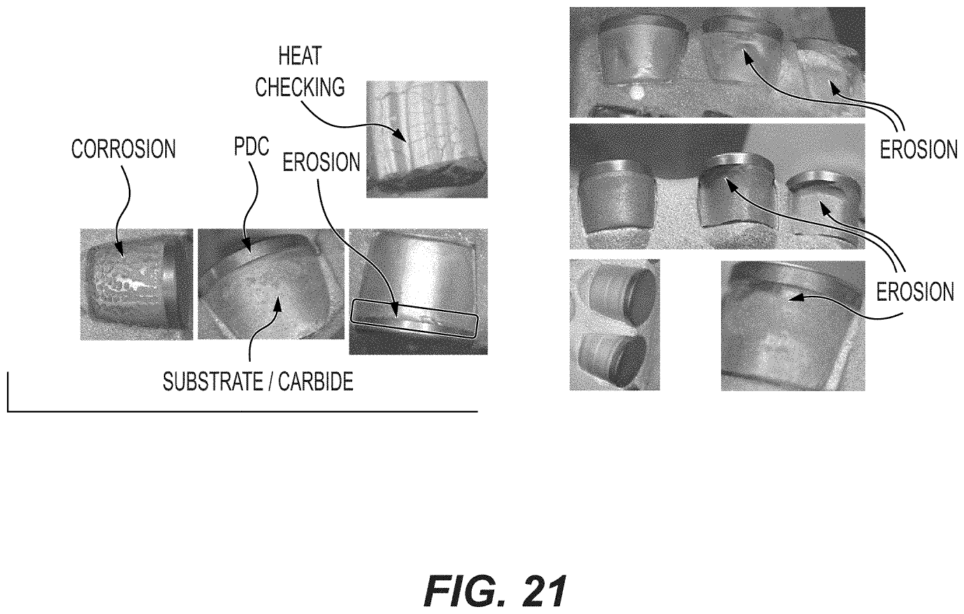

In a further embodiment, wear classifier system 1200 may be further configured to classify different types of substrate damage. Examples of FIG. 21 shows images of different types of substrate damage that may be classified by a wear classification tool. As shown in FIG. 21, types of substrate damage that may be classified include heat checking damage, corrosion, and erosion of the substrate.

In an embodiment, 2D image data and/or 3D scanner data can be used to train a neural network (NN) to identify erosion and corrosion on a PDC cutter substrate. For example, individual cutting elements such as PDC cutters can be separated into two main components, PDC diamond table and tungsten carbide substrate. 2D image data and/or 3D scanner data suitable for identifying erosion and corrosion on a PDC cutter substrate can be used in training dataset 1235.

Wear classifier tool 1210 can then be further configured to use ML engine 1230 (i.e., training stage 1420) train another NN to obtain a further trained ML model 1232 that can be used to identify erosion and corrosion on a PDC cutter substrate. After training is complete, ML engine 1230 can be further configured to receive input data 1405 made up of 2D image data and/or 3D scanner data of well tool 100 captured by camera 1702 and 3D scanner 1712. ML engine 1230 can then use an inference engine 1410 to process the input data 1405 using training dataset 1235 to identify erosion and corrosion on a PDC cutter substrate.

In a further embodiment, machine learning is used in step 302 to automate the identification of a particular well tool on a stand 206, 1706 or 1716. 2D image data and/or 3D scanner data suitable for identifying a particular well tool (such as a rotary drill bit) can be used in training dataset 1235. For example, wear classifier tool 1210 can be further configured to use ML engine 1230 (i.e., training stage 1420) train another NN to obtain a further trained ML model 1232 that can be used to identify a particular well tool. After training is complete, ML engine 1230 can be further configured to receive input data 1405 made up of 2D image data and/or 3D scanner data of well tool 100 captured by camera 1702 and 3D scanner 1712. ML engine 1230 can then use an inference engine 1410 to process the input data 1405 using training dataset 1235 to identify a particular well tool 100 on a stand 206, 1706 or 1716.

### Example Computer-Implemented Embodiments

In embodiments, system 1200 (including its components 1210-1235) can be implemented on one or more computing devices, such as, computing system 204. The computing devices may be at the same or different locations. A computing device can be any type of device having one or more processors and memory. For example, a computing device can be a workstation, mobile device (e.g., a mobile phone, personal digital assistant, tablet or laptop), computer, server, computer cluster, server farm, game console, set-top box, kiosk, embedded system, or other device having at least one processor and computer-readable memory. In addition to at least one processor and memory, such a computing device may include software, firmware, hardware, or a combination thereof. Software may include one or more applications and an operating system. Hardware can include, but is not limited to, a processor, memory and user interface display or other input/output device.

Aspects of computing embodiments may also include client and server sides (including remote users on remote computing devices coupled to system 1200) may be implemented electronically using hardware, software modules, firmware, tangible computer readable or computer usable storage media having instructions stored thereon, or a combination thereof and may be implemented in one or more computer systems or other processing systems.

Embodiments disclosed herein include:

Embodiment 1: A method of well tool inspection, comprising: training a neural network with a plurality of failure mode images; scanning a used well tool with a scanner to obtain wear input data; classifying one or more failure modes sustained by the used well tool using the trained neural network and the wear input data; and outputting classified failure mode data.

Embodiment 2: The method of embodiment 1, wherein the neural network comprises a multi-layer convolutional neural network.

Embodiment 3: The method of embodiments 1 or 2, further comprising storing a training dataset having scanned image data and associated labels.

Embodiment 4: The method of any of embodiments 1-3, further comprising storing a training dataset having scanned image data and associated labels representative of classification types of failure.

Embodiment 5: The method of any of embodiments 1-4, wherein the used well tool includes a plurality of cutting elements and wherein the labels are representative of classification types of failure in cutting elements.

Embodiment 6: The method of any of embodiments 1-5, wherein the labels are representative of classification types of failure in patterns among the cutting elements.

Embodiment 7: The method of any of embodiments 1-6, wherein the training dataset further includes historical data and live sensor data.

Embodiment 8: The method of any of embodiments 1-7, wherein the scanner includes a two-dimensional (2D) scanner and a three-dimensional (3D) scanner, and the scanning includes scanning a drill bit with the 2D scanner and 3D scanner to obtain 2D and 3D images respectively.

Embodiment 9: The method of any of embodiments 1-8, further comprising locating a discrete part of interest on the used well tool.

Embodiment 10: The method of any of embodiments 1-9, wherein the used well tool includes a plurality of cutting elements comprised of a substrate and diamond table, and further comprising the steps of: training a second neural network with a training dataset having a plurality of substrate damage images; scanning the used well tool with a scanner to obtain substrate damage input data; classifying one or more types of substrate damage sustained by the used well tool using the trained second neural network and the substrate damage input data; and outputting data representative of one or more classified types of substrate damage sustained by the used well tool.

Embodiment 11: The method of embodiment 10, wherein the types of substrate damage include one or more of heat checking damage, corrosion, or erosion.

Embodiment 12: The method of any of embodiments 1-11, further comprising the steps of: training a third neural network with a training dataset having a plurality of images of well tools; scanning a used well tool with the scanner to obtain well tool input data; identifying the used well tool using the trained third neural network and the well tool input data; and outputting data representative of the identified used well tool.

Embodiment 13: A well tool wear classification system comprising: a wear classifier tool configured to classify wear of a scanned well tool using a machine learning engine; and a computer-readable memory storing a training dataset and a trained ML model, wherein the training data set includes scanned image data and associated labels representative of classification types of failure.

Embodiment 14: The system of embodiment 13, wherein the trained ML model includes a neural network.

Embodiment 15: The system of embodiments 13 or 14, wherein the neural network comprises a multi-layer convolutional neural network.

Embodiment 16: The system of any of embodiments 13-15, wherein the used well tool includes a plurality of cutting elements and wherein the labels are representative of classification types of failure in cutting elements.

Embodiment 17: The system of any of embodiments 13-16, wherein the labels are representative of classification types of failure in patterns among the cutting elements.

Embodiment 18: The system of any of embodiments 13-17, wherein the training dataset further includes historical data and live sensor data.

Embodiment 19: The system of any of embodiments 13-18, further comprising a database coupled to the wear classifier tool, wherein the database is configured to stored historical data on scanner type, patterns of scanner cutting elements, sensor type, and age and usage conditions.

Embodiment 20: The system of any of embodiments 13-19, wherein the wear classifier tool is further configured to output data identifying a failure mode of the scanned well tool based on classification of input by the machine learning engine.

Embodiment 21: The system of any of embodiments 13-20, wherein the wear classifier tool is further configured to generate an alert for a user for certain types of failure modes.

Embodiment 22: The system of any of embodiments 13-21, further comprising: a scanning system including a 2D scanner and a 3D scanner, wherein the scanning system is configured to scan a drill bit with the 2D scanner and the 3D scanner to obtain 2D and 3D images respectively.

Embodiment 23: The system of embodiment 22, further comprising first and second robotic arms coupled to the 2D and 3D scanners respectively.

Embodiment 24: The system of embodiment 22, further comprising a robotic arm coupled to the 2D and 3D scanners.

Embodiment 25: The system of any of embodiments 22-24, wherein the 2D scanner comprises a digital camera.

Embodiment 26: A well tool wear classification system comprising: a camera configured to capture at least one image of a well tool representative of wear of the well tool; a 3D scanner configured to capture at least one image and distance data of the well tool; and a wear classifier tool configured to classify wear of the well tool using a machine learning engine provided with an image and distance data captured by the 3D scanner.

Embodiment 27: The system of embodiment 26, further comprising computer-readable memory storing a training dataset and a trained model, wherein the training data set includes training image data and associated labels representative of classification types of failure.

Embodiment 28: The system of embodiments 26 or 27, wherein the computer-readable memory further stores the image captured by the camera, whereby, the stored image can be processed or cropped for inclusion in a report on the wear of the well tool.

Therefore, the disclosed systems and methods are well adapted to attain the ends and advantages mentioned as well as those that are inherent therein. The particular embodiments disclosed above are illustrative only, as the teachings of the present disclosure may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope of the present disclosure. The systems and methods illustratively disclosed herein may suitably be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces. If there is any conflict in the usages of a word or term in this specification and one or more patent or other documents that may be incorporated herein by reference, the definitions that are consistent with this specification should be adopted.

As used herein, the phrase “at least one of” preceding a series of items, with the terms “and” or “or” to separate any of the items, modifies the list as a whole, rather than each member of the list (i.e., each item). The phrase “at least one of” allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

What is claimed is:

1. A method of well tool inspection, comprising:
training a neural network with a plurality of failure mode images;
scanning a used well tool with a scanner to obtain wear input data;
classifying one or more failure modes sustained by the used well tool using the trained neural network and the wear input data; and
outputting classified failure mode data.

2. The method of claim 1, wherein the neural network comprises a multi-layer convolutional neural network.

3. The method of claim 2, further comprising storing a training dataset having scanned image data and associated labels.

4. The method of claim 3, further comprising storing a training dataset having scanned image data and associated labels representative of classification types of failure.

5. The method of claim 4, wherein the used well tool includes a plurality of cutting elements and wherein the labels are representative of classification types of failure in cutting elements.

6. The method of claim 5, wherein the labels are representative of classification types of failure in patterns among the cutting elements.

7. The method of claim 4, wherein the training dataset further includes historical data and live sensor data.

8. The method of claim 1, wherein the scanner includes a two-dimensional (2D) scanner and a three-dimensional (3D) scanner, and the scanning includes scanning a drill bit with the 2D scanner and 3D scanner to obtain 2D and 3D images respectively.

9. The method of claim 1, further comprising locating a discrete part of interest on the used well tool.

10. The method of claim 1, wherein the used well tool includes a plurality of cutting elements comprised of a substrate and diamond table, and further comprising the steps of:
training a second neural network with a training dataset having a plurality of substrate damage images;
scanning the used well tool with a scanner to obtain substrate damage input data;
classifying one or more types of substrate damage sustained by the used well tool using the trained second neural network and the substrate damage input data; and
outputting data representative of one or more classified types of substrate damage sustained by the used well tool.

11. The method of claim 10, wherein the types of substrate damage include one or more of heat checking damage, corrosion, or erosion.

12. The method of claim 10, further comprising the steps of:
training a third neural network with a training dataset having a plurality of images of well tools;
scanning a used well tool with the scanner to obtain well tool input data;
identifying the used well tool using the trained third neural network and the well tool input data; and
outputting data representative of the identified used well tool.

13. A well tool wear classification system comprising:
a wear classifier tool configured to classify wear of a scanned well tool using a machine learning engine; and
a computer-readable memory storing a training dataset and a trained ML model, wherein the training data set includes scanned image data and associated labels representative of classification types of failure.

14. The system of claim 13, wherein the trained ML model includes a neural network.

15. The system of claim 14, wherein the neural network comprises a multi-layer convolutional neural network.

16. The system of claim 13, wherein the used well tool includes a plurality of cutting elements and wherein the labels are representative of classification types of failure in cutting elements.

17. The system of claim 16, wherein the labels are representative of classification types of failure in patterns among the cutting elements.

18. The system of claim 17, wherein the training dataset further includes historical data and live sensor data.

19. The system of claim 13, further comprising a database coupled to the wear classifier tool, wherein the database is configured to stored historical data on scanner type, patterns of scanner cutting elements, sensor type, and age and usage conditions.

20. The system of claim 19, wherein the wear classifier tool is further configured to output data identifying a failure mode of the scanned well tool based on classification of input by the machine learning engine.

21. The system of claim 20, wherein the wear classifier tool is further configured to generate an alert for a user for certain types of failure modes.

22. The system of claim 13, further comprising: a scanning system including a 2D scanner and a 3D scanner, wherein the scanning system is configured to scan a drill bit with the 2D scanner and the 3D scanner to obtain 2D and 3D images respectively.

23. The system of claim 22, further comprising first and second robotic arms coupled to the 2D and 3D scanners respectively.

24. The system of claim 22, further comprising a robotic arm coupled to the 2D and 3D scanners.

25. The system of claim 22, wherein the 2D scanner comprises a digital camera.

26. A well tool wear classification system comprising:
a camera configured to capture at least one image of a well tool representative of wear of the well tool;
a 3D scanner configured to capture at least one image and distance data of the well tool; and
a wear classifier tool configured to classify wear of the well tool using a machine learning engine provided with an image and distance data captured by the 3D scanner.

27. The system of claim 26, further comprising computer-readable memory storing a training dataset and a trained model, wherein the training data set includes training image data and associated labels representative of classification types of failure.

28. The system of claim 26, wherein the computer-readable memory further stores the image captured by the camera, whereby, the stored image can be processed or cropped for inclusion in a report on the wear of the well tool.
